(19) United States
(12) Patent Application Publication
(10) Pub. No.: US 2026/0078051 A1
(43) Pub. Date: Mar. 19, 2026

(54) CHEMICALLY STRENGTHENED GLASS, METHOD FOR PRODUCING CHEMICALLY STRENGTHENED GLASS, COVER GLASS, AND SOLAR CELL MODULE

(71) Applicant: AGC Inc., Tokyo (JP)

(72) Inventor: Taku MURASUGI, Tokyo (JP)

(73) Assignee: AGC Inc., Tokyo (JP)

(21) Appl. No.: 19/326,424

(22) Filed: Sep. 11, 2025

(30) Foreign Application Priority Data
Sep. 19, 2024 (JP) 2024-161606

(51) Int. Cl. C03C 21/00; C03C 3/095; C03C 3/097

(52) U.S. Cl. CPC C03C 21/002; C03C 3/095; C03C 3/097

(57) ABSTRACT

Provided is chemically strengthened glass excellent in drop strength. The chemically strengthened glass of the present invention satisfies the relationships of following formulas (1) and (2):

$$\vert CT \vert \leq - 170 t + 175 \qquad ( 1 )$$

$$190 t - 124 \leq {CS}_{120} \qquad ( 2 )$$

where CT represents stress, in units of MPa, at a sheet thickness center position of the chemically strengthened glass; |CT| represents an absolute value of the stress CT; t represents a sheet thickness of the chemically strengthened glass in units of mm; and CS₁₂₀ represents compressive stress, in units of MPa, at a depth of 120 μm from a surface of the chemically strengthened glass.

### TECHNICAL FIELD

The present invention relates to chemically strengthened glass.

The present invention also relates to a method for producing chemically strengthened glass.

The present invention further relates to a cover glass including the chemically strengthened glass and a solar cell module including the cover glass.

### BACKGROUND ART

In recent years, cover glasses have been used for the purpose of protection and appearance improvement of display devices of mobile phones, smartphones, tablet terminals, in-vehicle display systems and the like. The cover glasses for these applications are required to have high strength to prevent breakage by impact etc.

Such cover glasses may also be used for protection of solar cell modules and the like.

Conventionally known is a technique for improving the surface strength of glass by chemically strengthening the glass through immersion in a molten salt of potassium nitrate etc. For example, Patent Document 1 discloses that the surface strength of sheet glass is improved by chemically strengthening the glass through immersion in a molten salt of potassium nitrate. More specifically, this patent document discloses production of sheet glass with improved strength by chemical strengthening treatment of Li-containing glass with a Na-containing molten salt and then with a K-containing molten salt. Further, this patent document describes that the mechanism for strengthening sheet glass through the above chemical treatment is due to compressive stress caused by exchange of alkali metals.

### PRIOR ART DOCUMENTS

### Patent Documents

Patent Document 1: WO2022/004808

### DISCLOSURE OF INVENTION

### Technical Problem

Recent years have seen thickness adjustment of cover glasses in response to various demands. For example, there has recently been a trend that the thickness of cover glasses needs to be reduced for weight and thickness reductions of casings.

The present inventor has recognized that cover glasses, when adjusted in thickness, may decrease in drop strength and need to be improved in strength. In particular, cover glasses tend to decrease in drop strength with thickness reduction and thus need to be improved in strength.

The present invention has been made in view of the above-mentioned problem. It is an object of the present invention to provide chemically strengthened glass excellent in drop strength.

It is another object of the present invention to provide a method for producing chemically strengthened glass.

It is still another object of the present invention to provide a cover glass and a solar cell module.

### Solution to Problem

As a result of intensive studies made on the above-mentioned problem, the present inventor has found that chemically strengthened glass satisfying predetermined relationships between its stress values and sheet thickness achieves excellent drop strength, and thus accomplished the present invention.

In other words, the present inventor has found the following solutions to the above-mentioned problem.

[1] Chemically strengthened glass satisfying relationships of the following formulas (1) and (2):

$$\vert CT \vert \leq - 170 t + 175 \qquad ( 1 )$$

$$190 t - 124 \leq {CS}_{120} \qquad ( 2 )$$

where CT represents stress, in units of MPa, at a sheet thickness center position of the chemically strengthened glass; |CT| represents an absolute value of the stress CT; t represents a sheet thickness of the chemically strengthened glass in units of mm; and CS₁₂₀ represents compressive stress, in units of MPa, at a depth of 120 μm from a surface of the chemically strengthened glass.

[2] The chemically strengthened glass according to [1], wherein a depth of compressive stress layer DOC of the chemically strengthened glass is greater than or equal to 0.20 times the sheet thickness of the chemically strengthened glass.

[3] The chemically strengthened glass according to [2], wherein a stress profile of the chemically strengthened glass has a slope with an absolute value of 1.00 or less from the depth of compressive stress layer DOC to the sheet thickness center position.

[4] The chemically strengthened glass according to any one of [1] to [3], wherein the chemically strengthened glass satisfies a relationship of the following formula (3):

$$150 t - 50 \leq {CS}_{50} \qquad ( 3 )$$

where CS₅₀ represents compressive stress, in units of MPa, at a depth of 50 μm from the surface of the chemically strengthened glass; and t represents the sheet thickness of the chemically strengthened glass in units of mm.

[5] The chemically strengthened glass according to any one of [1] to [4], wherein the chemically strengthened glass has a Young's modulus of 80 GPa or higher at an in-plane center position thereof.

[6] The chemically strengthened glass according to any one of [1] to [5], wherein the chemically strengthened glass has a fracture toughness value K_{IC} of 0.80 MPa·m^{1/2} or higher at an in-plane center position thereof.

[7] The chemically strengthened glass according to any one of [1] to [6], wherein the chemically strengthened glass has a composition at the sheet thickness center position thereof comprising, in mole percentage on an oxide basis,
55 to 75% of SiO₂,
3 to 18% of Al₂O₃,
17 to 30% of Li₂O,
0 to 3% of Na₂O,
0 to 1% of K₂O,
0 to 10% of MgO,
0 to 10% of CaO,
0 to 5% of SrO,
0 to 5% of ZnO,
0 to 3% of TiO₂,
0 to 5% of ZrO₂,
0 to 1% of SnO₂,
0 to 3% of P₂O₅,
0 to 10% of B₂O₃, and
0 to 3% of Y₂O₃.

[8] The chemically strengthened glass according to any one of [1] to [7], wherein the chemically strengthened glass is in the form of crystallized glass and has a transmittance of 85% or higher.

[9] The chemically strengthened glass according to any one of [1] to [8], wherein the compressive stress CS₁₂₀ is 0 MPa or lower.

[10] The chemically strengthened glass according to any one of [1] to [9], wherein the sheet thickness is 0.6 mm or smaller.

[11] The chemically strengthened glass according to any one of [1] to [10], wherein a stress profile of the chemically strengthened glass, as measured in a depth direction by a scattered light photoelastic stress meter, has a first derivative value with an absolute value of 1.80 or less at any depth from the depth of 120 μm from the surface to the sheet thickness center position.

[12] The chemically strengthened glass according to [2] or [3], wherein a stress profile of the chemically strengthened glass, as measured in a depth direction by a scattered light photoelastic stress meter, has a first derivative value with an absolute value of 1.80 or less at the depth of compressive stress layer DOC.

[13] The chemically strengthened glass according to [2] or [3], wherein a stress profile of the chemically strengthened glass, as measured in a depth direction by a scattered light photoelastic stress meter device, has a first derivative value such that a value obtained by dividing an absolute value of the first derivative value at the depth of compressive stress layer DOC by an absolute value of the first derivative value at the depth of 120 μm from the surface is 1.20 or less.

[14] A method for producing the chemically strengthened glass as defined in any one of [1] to [13], comprising:
performing, on glass for chemical strengthening, first chemical strengthening treatment with a first molten salt containing 90 mass % or more of a sodium salt and 2 mass % or more of a lithium salt to the total mass of the first molten salt; and
after the first chemical strengthening treatment, performing, on the glass for chemical strengthening, second chemical strengthening treatment with a second molten salt containing 90 mass % or more of a potassium salt to the total mass of the second molten salt,
the glass for chemical strengthening having a composition at a sheet thickness center position thereof comprising, in mole percentage on an oxide basis,
60 to 72% of SiO₂,
10 to 20% of Al₂O₃,
3 to 12% of Li₂O,
0.5 to 6% of Na₂O, and
1 to 3% of K₂O.

[15] The method for producing chemically strengthened glass according to [14], wherein the ratio of the content of the lithium salt in the first molten salt to the content of Li₂O in the composition of the chemically strengthened glass is from 0.1 to 1.0 in terms of molar ratio.

[16] The method for producing chemically strengthened glass according to [14] or [15], wherein a treatment time of the first chemical strengthening treatment is 150 minutes or more, and a treatment time of the second chemical strengthening treatment is 90 minutes or more.

[17] A cover glass comprising the chemically strengthened glass as defined in any one of [1] to [13].

[18] A solar cell module comprising the cover glass as defined in [17].

### Advantageous Effects of Invention

The present invention provides chemically strengthened glass with excellent drop strength.

The present invention also provides a method for producing chemically strengthened glass.

The present invention further provides a cover glass and a solar cell module.

### BRIEF DESCRIPTION OF DRAWINGS

FIG. 1 is a diagram illustrating a method for determining various characteristic temperatures from a differential scanning calorimetry (DSC) curve of glass.

FIG. 2 is a schematic view illustrating a sample for measurement of fracture toughness value K_{IC} by the double cleavage drilled compression (DCDC) method.

FIG. 3 is a diagram illustrating a K1-v curve, which indicates a relationship between stress intensity factor K1 (unit: MPa·m^{1/2}) and crack propagation rate v (unit: m/s), as used for measurement of fracture toughness value K_{IC} by the DCDC method.

### DESCRIPTION OF EMBODIMENTS

Hereinafter, the present invention will be described in detail below.

It should be understood that the following typical embodiments of the present invention are intended as illustrative only and are not intended to limit the present invention thereto.

In the present specification, “chemically strengthened glass” refers to glass having been subjected to chemical strengthening treatment; and “glass for chemical strengthening” refers to glass before being subjected to chemical strengthening treatment.

In the present specification, a glass composition of glass for chemical strengthening may also be referred to as a base glass composition of chemically strengthened glass. Since chemically strengthened glass usually has a compressive stress layer formed in a surface portion thereof by ion exchange, the glass composition of a non-ion-exchanged portion of the chemically strengthened glass corresponds to the base glass composition of the chemically strengthened glass.

In the present specification, a glass composition is expressed in mole percentage on the oxide basis; and mol % may be simply referred to as %. Further, a numerical range expressed using “to” means a range including numerical values described before and after “to” as lower and upper limits.

In a glass composition, “substantially free of” means that it is not contained except as an unavoidable impurity in raw material etc., that is, it is not intentionally contained. More specifically, the content of a component other than those described as the glass composition is, for example, preferably less than 0.1 mol %, more preferably 0.08 mol % or less, still more preferably 0.05 mol % or less.

In the present specification, a “stress profile” refers to a pattern representing a value of compressive stress with a depth from glass surface taken as a variable. A negative compressive stress value means tensile stress.

A stress profile of glass can be measured by a scattered light photoelastic stress meter (SLP) and an optical waveguide surface stress meter (also called a film stress measurement instrument (FSM)).

In the present specification, a stress profile measured by a scattered light photoelastic stress meter (SLP) is referred to as a “SLP stress profile”; and a stress profile measured by a film stress measurement instrument (FSM) is referred to as a “FSM stress profile”.

The film stress measurement instrument (FSM) can accurately measure stress in glass in a short time. As an example of the FSM, FSM-6000 manufactured by Orihara Industrial Co., Ltd. may be mentioned. In principle, however, the FSM can only measure stress when the refractive index decreases from the sample surface to the inside. A layer formed in chemically strengthened glass by exchanging sodium ions inside the glass with external potassium ions has a refractive index decreasing from the surface to the inside and can be measured for its stress by the FSM. A layer formed in chemically strengthened glass by exchanging lithium ions inside the glass with external sodium ions cannot be accurately measured for its stress by the FSM.

On the other hand, the scattered light photoelastic stress meter (SLP) can measure stress regardless of the refractive index distribution. As examples of the SLP, SLP-1000 and SLP-2000 manufactured by Orihara Industrial Co., Ltd. may be mentioned. By combining such a scattered light photoelastic stress meter with software SlpIV_up3 (ver. 2019.01.10.001) attached thereto, highly accurate stress measurement is possible. However, the SLP is susceptible to surface scattering and may not be able to accurately measure stress in the vicinity of the sample surface.

For the above reasons, the combined use of two types of measurement devices, i.e., the film stress measurement instrument (FSM) and the scattered light photoelastic stress meter (SLP) enables accurate stress measurement throughout the entire thickness of chemically strengthened glass.

In the present specification, a stress profile obtained by combination of the information from the SLP and the information from the FSM is referred to as a “combined stress profile”.

A stress profile in the vicinity of the glass surface can be measured by the FSM with reference to a known method. A stress profile inside the glass from the glass surface to a depth of several tens μm can be measured by the SLP with reference to a known method. Examples of such known methods are those disclosed in WO2018/056121 and WO2017/115811.

In the present specification, a “depth of compressive stress layer” refers to a depth at which the compressive stress value becomes zero.

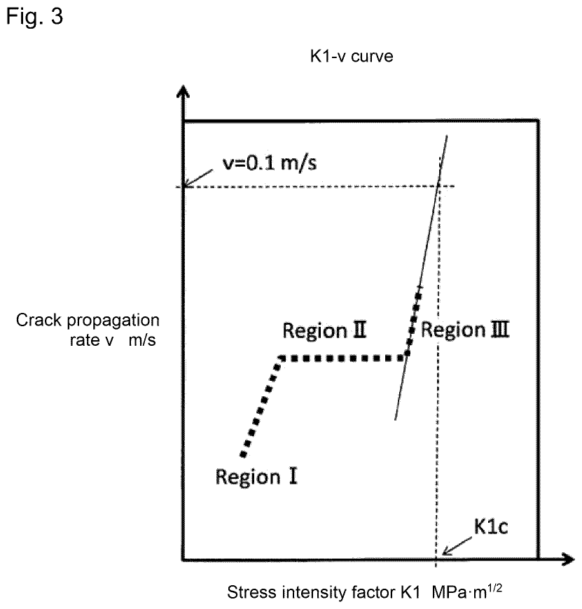

In the present specification, a “fracture toughness value K_{IC}” is measured with reference to the DCDC method (see, for reference, M. Y. He, M. R. Turner and A. G. Evans, Acta Metall. Mater. 43 (1995) 3453.). More specifically, using a sample having a shape shown in FIG. 2 and a SHIMADZU autograph AGS-X5KN, measured is a K1-v curve that indicates a relationship between stress intensity factor K1 (unit: MPa·m^{1/2}) and crack propagation rate v (unit: m/s) as shown in FIG. 3. The obtained Region III data is regressed to a linear expression, and by extrapolation of the linear expression, the stress intensity factor K1 corresponding to v=0.1 m/s is taken as the fracture toughness value K_{IC}.

### <Chemically Strengthened Glass>

The chemically strengthened glass of the present invention satisfies the relationships of the following relationships (1) and (2).

$$\vert CT \vert \leq - 170 t + 175 \qquad ( 1 )$$

$$190 t - 124 \leq {CS}_{120} \qquad ( 2 )$$

In the formulas (1) and (2), CT represents stress (unit: MPa) at a thickness center position of the chemically strengthened glass; |CT| represents an absolute value (unit: MPa) of the stress CT; t represents a sheet thickness (unit: mm) of the chemically strengthened glass; and CS₁₂₀ represents compressive stress (unit: MPa) at a depth of 120 μm from a surface of the chemically strengthened glass.

The mechanism by which the chemically strengthened glass of the present invention, satisfying the relationships of the formulas (1) and (2), achieves excellent drop strength is not always certain, but is assumed to be as follows by the present inventor.

It is considered that breakage of glass occurs as a result of propagation of scratches on a surface of the glass.

The chemically strengthened glass of the present invention has compressive stress caused on its surface by chemical strengthening and satisfies the relationship of the formula (1). This easily leads to high drop strength.

Further, the chemically strengthened glass of the present invention satisfies the relationship of the formula (2). The relationship of the formula (2) means that the compressive stress CS₁₂₀ at a depth of 120 μm in the chemically strengthened glass is higher than or equal to a predetermined value with respect to the sheet thickness. In the chemically strengthened glass of the present invention satisfying the relationship of the formula (2), scratches, even when reaching a deep point (for example, a depth position of 120 μm), remain in the predetermined range of compressive stress CS₁₂₀ and are unlikely to propagate. This easily leads to high drop strength.

From the above reasons, the chemically strengthened glass of the present invention is considered to be excellent in drop strength.

In the following, the conditions satisfied by the chemically strengthened glass of the present invention will be described in more detail.

### [Sheet Thickness]

The sheet thickness of the chemically strengthened glass of the present invention is preferably 0.8 mm or smaller, more preferably 0.7 mm or smaller, still more preferably 0.6 mm or smaller.

Further, the sheet thickness of the chemically strengthened glass of the present invention is usually 0.1 mm or greater, preferably 0.2 mm or greater, more preferably 0.3 mm or greater, still more preferably 0.4 mm or greater.

### [Compressive Stress]

The compressive stress (CS₁₂₀) at a depth of 120 μm in the chemically strengthened glass of the present invention is set such that the relationship of the above formula (2) is satisfied between the compressive stress CS₁₂₀ and the sheet thickness t.

The compressive stress CS₁₂₀ is preferably −30 MPa or higher, more preferably −25 MPa or higher, still more preferably −20 MPa or higher, particularly preferably −15 MPa or higher, most preferably −10 MPa or higher. The compressive stress CS₁₂₀ may be 0 MPa or higher or may be 10 MPa or higher. The compressive stress CS₁₂₀ is usually 50 MPa or lower. When the sheet thickness is 0.6 mm or smaller, the compressive stress CS₁₂₀ is often 20 MPa or lower. The compressive stress CS₁₂₀ may be 0 MPa or lower.

The compressive stress CS₁₂₀ can be determined from a SLP stress profile.

The compressive stress (CS₅₀) at a depth of 50 μm in the chemically strengthened glass of the present invention is preferably 20 MPa or higher, more preferably 30 MPa or higher, still more preferably 40 MPa or higher. Further, the compressive stress CS₅₀ is preferably 200 MPa or lower, more preferably 150 MPa or lower, still more preferably 100 MPa or lower, particularly preferably 75 MPa or lower, most preferably 60 MPa or lower, with a view to achieving higher drop strength.

The compressive stress CS₅₀ can be determined from a SLP stress profile.

Furthermore, it is preferable that the chemically strengthened glass of the present invention satisfies the relationship of the following formula (3):

$$150 t - 50 \leq {CS}_{50} \qquad Formula ( 3 )$$

where CS₅₀ represents compressive stress (unit: MPa) at a depth of 50 μm in the chemically strengthened glass; and t represents the sheet thickness (unit: mm) of the chemically strengthened glass.

The compressive stress (CS₀) at the surface of the chemically strengthened glass of the present invention is preferably 700 MPa or higher, more preferably 800 MPa or higher, still more preferably 900 MPa or higher, particularly preferably 1000 MPa or higher.

Here, the surface compressive stress CS₀ can be determined by a surface stress meter such as FSM.

The above respective compressive stress values can be adjusted according to, for example, the conditions of chemical strengthening treatment described later.

### [Depth of Compressive Stress Layer]

The depth of compressive stress layer DOC of the chemically strengthened glass of the present invention is preferably 80 μm or greater, more preferably 90 μm or greater, still more preferably 100 μm or greater. Further, the depth of compressive stress layer DOC is usually 200 μm or smaller, preferably 150 μm or smaller, more preferably 130 μm or smaller, still more preferably 120 μm or smaller.

The depth of compressive stress layer DOC can be determined from a SLP stress profile.

The depth of compressive stress layer DOC is preferably greater than or equal to 0.16 times the sheet thickness, more preferably greater than or equal to 0.17 times the sheet thickness, still more preferably greater than or equal to 0.20 times the sheet thickness. Further, the depth of compressive stress layer DOC is usually smaller than or equal to 0.30 times the sheet thickness, often smaller than or equal to 0.25 times the sheet thickness, preferably smaller than or equal to 0.23 times the sheet thickness.

### [Tensile Stress]

Since the chemically strengthened glass of the present invention has compressive stress in the vicinity of its surface, tensile stress acts inside the chemically strengthened glass so as to balance the compressive stress. In other words, the stress CT at the sheet thickness center position of the chemically strengthened glass of the present invention is usually tensile stress (compressive stress negative in value).

As mentioned above, the stress CT at the sheet thickness center position of the chemically strengthened glass of the present invention is set such that the relationship of the above formula (1) is satisfied between the sheet thickness t and the stress CT.

The absolute value of the stress CT is preferably 30 MPa or more, more preferably 40 MPa or more, still more preferably 50 MPa or more, and may be 70 MPa or more. Further, the absolute value of the stress CT is preferably 100 MPa or less, more preferably 95 MPa or less, still more preferably 90 MPa or less.

### [Slope of Stress Profile]

When fitting is performed on the SLP stress profile by using an appropriate function, the function after the fitting can be differentiated for further analysis of the SLP stress profile. Here, the SLP stress profile has a depth (unit: μm) on the horizontal axis and a compressive stress value (unit: MPa) on the vertical axis.

For the fitting of the SLP stress profile, the following function (formula (FS)) can be used.

$$σ ( x ) = {a}_{1} erfc ( {a}_{2} x ) + {a}_{3} erfc ( {a}_{4} x ) + {a}_{5} \qquad ( FS )$$

In the formula (FS), aᵢ (i=1 to 5) each represents a fitting parameter; erfc represents a complementary error function; and x represents a depth.

The complementary error function (erfc(x)) is defined by the following formula.

$$erfc ( x ) = \frac{2}{\sqrt{π}} {\int }_{x}^{∞} {e}^{- {t}^{2}} dt$$

The fitting can be performed using software SlpIV (ver. 2019.01.10.001) attached to a scattered light photoelastic stress meter (model SLP-1000 manufactured by Orihara Industrial Co., Ltd.). More specifically, the fitting parameters are optimized by minimizing the residual sum of squares of the obtained raw data and the above function. The respective settings are herein applied by designation or selection as follows: the measurement processing condition is single shot; the measurement region processing adjustment item is an edge method on a surface; the internal surface edge is 6.0 μm; the internal left-right edge is automatic; the internal deep portion edge is automatic (sample thickness center); and the extension of a phase curve to the sample thickness center is a fitting curve.

The function obtained by the above fitting process is first-order differentiable and is second-order differentiable. This function is hereinafter also referred to as σ_{f}(x).

A first derivative function σ_{f}′(x) is obtained by differentiating the function (σ_{f}(x)) with respect to the depth x. When a value of the depth x is substituted for the first derivative function σ_{f}′(x), a slope of the first derivative function σ_{f}(x) at such a depth (a first derivative value) is obtained.

In the chemically strengthened glass of the present invention, the absolute value of the first derivative value is preferably 1.80 or less, more preferably 1.20 or less, still more preferably 0.80 or less, most preferably 0.60 or less, at any position from the depth of 120 μm from the surface to the sheet thickness center position. Further, the absolute value of the first derivative value is usually 0.10 or more, preferably 0.20 or more, more preferably 0.30 or more, at any position from the depth of 120 μm from the surface to the sheet thickness center position.

Furthermore, in the chemically strengthened glass of the present invention, the absolute value of the first derivative value at the depth of compressive stress layer DOC is preferably 1.80 or less, more preferably 1.40 or less, still more preferably 1.00 or less. The absolute value of the first derivative value at the depth of compressive stress layer DOC is preferably 0.10 or more, more preferably 0.20 or more, still more preferably 0.30 or more.

In the chemically strengthened glass of the present invention, the absolute value of the slope as calculated from the compressive stress value at the depth of compressive stress layer DOC and the compressive stress value at the sheet thickness center position is preferably 1.00 or less, more preferably 0.95 or less, still more preferably 0.90 or less. It is also preferable that the absolute value of the slope is 0.60 or less. The absolute value of the slope is usually 0.20 or more, preferably 0.30 or more.

The absolute value of the slope is determined as an absolute value of the result of division of the above stress CT by a subtraction of the depth of compressive stress layer DOC from the depth at the sheet thickness center position.

In the stress profile of the chemically strengthened glass of the present invention as measured in the depth direction by a scattered light photoelastic stress meter, the value obtained by dividing the absolute value of the first derivative value at the depth of compressive stress layer DOL by the absolute value of the first derivative value at the depth of 120 μm from the surface (hereinafter also referred to as a “first derivative ratio”) is preferably 1.20 or smaller. The first derivative ratio is preferably 0.80 or greater. With a view to achieving higher drop strength, the first derivative ratio is more preferably 0.90 or greater, still more preferably 1.00 or greater. Further, the first derivative ratio is more preferably 1.15 or smaller with a view to achieving higher drop strength.

### [Young's Modulus]

The Young's modulus at an in-plane center position of the chemically strengthened glass of the present invention is preferably 80 GPa or higher, more preferably 83 GPa or higher, still more preferably 85 GPa or higher, particularly preferably 90 GPa or higher. Here, the Young's modulus at the in-plane center position of the chemically strengthened glass refers to a Young's modulus measured at a center position in the in-plane direction of the sheet-shaped chemically strengthened glass. The center position in the in-plane direction corresponds to the center of gravity in the in-plane direction and, when the chemically strengthened glass has a square shape in plan view, corresponds to the point of intersection of the diagonals.

The Young's modulus can be adjusted according to not only the composition (base glass composition) of glass (glass for chemical strengthening) used for production of the chemically strengthened glass, but also the heat treatment conditions such as heat treatment temperature, heat treatment time, cooling rate and temperature profile of the glass for chemical strengthening. For example, when the base glass composition is a composition that can form crystallized glass, the value of the Young's modulus is easily changed depending on the heat treatment conditions.

Furthermore, the Young's modulus at the sheet thickness center position of the chemically strengthened glass of the present invention is preferably 80 GPa or higher, more preferably 83 GPa or higher, still more preferably 85 GPa or higher, particularly preferably 90 GPa or higher. Here, the Young's modulus of the glass for chemical strengthening corresponds to the Young's modulus at the sheet thickness center position of the chemically strengthened glass.

In the present specification, both of the Young's modulus of the glass for chemical strengthening and the Young's modulus at the sheet thickness center position of the chemically strengthened glass refer to values measured by the ultrasonic pulse method. The detailed measurement method is as described later in Examples.

### [Fracture Toughness Value]

With a view to achieving higher breakage strength, the fracture toughness value (K_{IC}) at the sheet thickness center position of the chemically strengthened glass of the present invention is preferably 0.75 MPa·m^{1/2} or higher, more preferably 0.80 MPa·m^{1/2} or higher, still more preferably 0.85 MPa·m^{1/2} or higher. The fracture toughness value K_{IC} is usually 2.00 MPa·m^{1/2} or lower, preferably 1.80 MPa·m^{1/2} or lower.

The method for measuring the fracture toughness value K_{IC} at the sheet thickness center position of the chemically strengthened glass of the present invention is as described later in Examples.

The fracture toughness value of the glass for chemical strengthening corresponds to the fracture toughness value at the sheet thickness center position of the chemically strengthened glass.

The fracture toughness value K_{IC} can be adjusted, for example, by the same method as the Young's modulus.

### [Transmittance]

The transmittance of the chemically strengthened glass of the present invention is preferably 85% or higher.

The transmittance of the chemically strengthened glass is measured by a spectrophotometer.

More specifically, a measurement sample with a thickness of 0.50 mm is prepared and measured by a spectrophotometer LAMBDA 950 manufactured by PerkinElmer Inc. The average transmittance (unit: %) of the sample in the wavelength range of 380 to 780 nm is determined from the measurement results and is taken as the transmittance of the chemically strengthened glass of the present invention.

The transmittance of the chemically strengthened glass of the present invention is more preferably 90% or higher, and may be 95% or higher. The transmittance of the chemically strengthened glass of the present invention is usually 99% or lower.

Furthermore, it is preferable that the chemically strengthened glass of the present invention is in the form of crystallized glass and has the above transmittance.

### [Composition]

The chemically strengthened glass of the present invention is produced by performing chemical strengthened treatment on sheet glass to be chemically strengthened (glass for chemical strengthening).

The preferable composition (base glass composition) of the glass for chemical strengthening will be described below. Here, the base glass composition corresponds to the composition of the chemically strengthened glass at the sheet thickness center position.

In the following, preferable examples of the base glass composition will be described as first and second embodiments.

### First Embodiment

The base glass composition of the first embodiment includes, in mole percentage on the oxide basis,
60 to 72% of SiO₂,
10 to 20% of Al₂O₃,
3 to 12% of Li₂O,
0.5 to 6% of Na₂O, and
0 to 3% (preferably 1 to 3%) of K₂O.

It is particularly preferable that the base glass composition of the first embodiment includes, in mole percentage on the oxide basis,
60 to 72% of SiO₂,
10 to 20% of Al₂O₃,
3 to 12% of Li₂O,
0.5 to 6% of Na₂O,
0 to 3% of K₂O,
0 to 10% of MgO,
0 to 10% of CaO,
0 to 5% of SrO,
0 to 5% of ZnO,
0 to 3% of TiO₂,
0 to 3% of ZrO₂,
0 to 1% of SnO₂,
0 to 1% of P₂O₅,
0 to 10% of B₂O₃, and
0 to 3% of Y₂O₃,
   wherein the sum of the content of Li₂O, the content of Na₂O and the content of K₂O, referred to as the total content R, is 5 to 20%; the ratio of the content of Li₂O to the total content R is from 0.5 to 0.95; and the product of the ratio of the content of Li₂O to the total content R, the ratio of the content of Na₂O to the total content R and the ratio of the content of K₂O to the total content R is from 0.001 to 0.03.

The respective components of the base glass composition of the first embodiment will be described in more detail below. In the following, the content of SiO₂ in mole percentage on the oxide basis may be occasionally referred to as [SiO₂]; and the same applies to the other components.

SiO₂ is a component for forming a network structure in glass. SiO₂ is also a component for improving the chemical resistance of glass and a component for suppressing the occurrence of cracks in glass due to scratches caused on a surface of the glass.

With a view to improvement of chemical resistance, the content of SiO₂ is more preferably 60.0% or more, still more preferably 62.0% or more, particularly preferably 64.0% or more, most preferably 66.0% or more. On the other hand, the content of SiO₂ is more preferably 70.0% or less, still more preferably 68.0% or less, particularly preferably 67.0% or less, with a view to obtaining good meltability.

Al₂O₃ is a component for improving the ion exchange performance of glass during chemical strengthening to increase surface compressive stress in the glass after the chemical strengthening.

From the viewpoint of obtaining the above effects, the content of Al₂O₃ is more preferably 10.0% or more, still more preferably in the following order: 10.5% or more; and 11.0% or more. On the other hand, it may be required that: crystals are difficult to grow during melting of the glass; devitrification defects are less likely to occur in the glass, thereby easily achieving a higher yield; or the glass is made lower in high-temperature viscosity and easier to melt. From such viewpoints, the content of Al₂O₃ is more preferably 15.0% or less, still more preferably in the following order: 14.0% or less; 13.5% or less; and 13.0% or less.

Each of SiO₂ and Al₂O₃ acts to stabilize the structure of glass. The total content of SiO₂ and Al₂O₃ is preferably 74.0% or more, more preferably 76.0% or more, still more preferably 77.0% or more, with a view to reduction of brittleness.

Further, each of SiO₂ and Al₂O₃ tends to raise the melting temperature of glass. From the viewpoint of ease of glass melting, the total content of SiO₂ and Al₂O₃ is preferably 83.0% or less, more preferably 82.0% or less, still more preferably 81.0% or less, particularly preferably 80.5% or less.

Li₂O is a component capable of ion exchange reaction and is a component for improving the meltability of glass. When Li₂O is contained in glass, a stress profile with higher surface compressive stress and thick compressive stress layer is easily obtained by exchanging Li ions on the glass surface with external Na ions to introduce Na ions to the inside of the glass and then exchanging the introduced Na ions with external K ions. From the viewpoint of easily obtaining a preferable stress profile, the content of Li₂O is more preferably 8.0% or more, still more preferably in the following order: 9.0% or more; 9.5% or more; 10.0% or more; 10.2% or more; and 10.4% or more.

On the other hand, from the viewpoint of lowering the rate of crystal growth during glass forming and suppressing a deterioration of quality due to devitrification, the content of Li₂O is more preferably 11.8% or less, still more preferably in the following order: 11.5% or less; and 11.0% or less.

Na₂O and K₂O are components for improving the meltability of glass and lowering the rate of crystal growth during glass forming. With a view to not only obtaining these effects but also improving the ion exchange performance of the glass, it is preferable that Na₂O and K₂O are contained in small amounts.

Na₂O is a component capable of ion exchange reaction during chemical strengthening treatment with a potassium salt, and is a component for lowering the viscosity of glass. From the viewpoint of obtaining the above effects, the content of Na₂O is preferably 1% or more, more preferably in the following order: 1.5% or more; 2.5% or more; 3.0% or more; and 4.0% or more.

K₂O is a component for not only suppressing devitrification by suppressing an increase of devitrification temperature, but also improving the ion exchange performance of glass. The content of K₂O is more preferably 0.1% or more, still more preferably 0.15% or more, particularly preferably in the following order: 0.2% or more; 0.5% or more; and 1.0% or more.

The sum of the content of Li₂O, the content of Na₂O and the content of K₂O, referred to as the total content R, is more preferably 8% or more, still more preferably 9% or more, particularly preferably 12% or more, most preferably 15% or more, from the viewpoint of suppressing an increase of devitrification temperature and lowering the rate of crystal growth.

The ratio of the content of Li₂O to the total content R ([Li₂O]/([Li₂O]+[Na₂O]+[K₂O]); hereinafter also referred to as “Li₂O/R₂O”) is preferably 0.52 or higher, more preferably 0.55 or higher, from the viewpoint of further improvement of chemical strengthening properties in terms of compressive stress in a deeper layer portion of the glass. With a view to achieving higher chemical resistance, the Li₂O/R₂O is preferably 0.90 or lower, more preferably 0.85 or lower, particularly preferably 0.75 or lower.

The ratio of the content of Na₂O to the total content R ([Na₂O]/([Li₂O]+[Na₂O]+[K₂O]); hereinafter also referred to as “Na₂O/R₂O”) is preferably higher than 0.08 or higher, more preferably 0.15 or higher, still more preferably 0.20 or higher, from the viewpoint of further improvement of chemical strengthening properties in terms of compressive stress in a deeper layer portion of the glass. The Na₂O/R₂O is preferably 0.60 or lower, more preferably 0.50 or lower, still more preferably 0.40 or lower, particularly preferably 0.35 or lower, with a view to achieving higher chemical resistance.

The ratio of the content of K₂O to the total content R ([K₂O]/([Li₂O]+[Na₂O]+[K₂O]); hereinafter also referred to as “K₂O/R₂O”) is preferably 0.01 or higher, more preferably 0.015 or higher, still more preferably 0.02 or higher, particularly preferably 0.08 or higher, with a view to achieving higher glass electrical resistance. The K₂O/R₂O is preferably 0.50 or lower, more preferably 0.40 or lower, still more preferably 0.30 or lower, particularly preferably 0.20 or lower, from the viewpoint of further improvement of chemical strengthening properties in terms of compressive stress in the vicinity of the glass surface.

The product of the Li₂O/R₂O, the Na₂O/R₂O and the K₂O/R₂O is preferably 0.002 or higher, more preferably 0.01 or higher, still more preferably 0.015 or higher, from the viewpoint of suppressing an increase of devitrification temperature. The above product is preferably 0.028 or lower from the viewpoint of improvement of chemical resistance.

The ratio of the content of Al₂O₃ to the total content R ([Al₂O₃]/([Li₂O]+[Na₂O]+[K₂O]); hereinafter also referred to as “Al₂O₃/R₂O”) is preferably 0.20 or higher, more preferably 0.30 or higher, still more preferably 0.40 or higher, particularly preferably 0.50 or higher. The Al₂O₃/R₂O is preferably 1.50 or lower, more preferably 0.80 or lower, still more preferably 0.75 or lower, particularly preferably 0.70 or lower, most preferably 0.65 or lower.

The ratio of the content of K₂O to the content of Na₂O (hereinafter also referred to as “[K₂O]/[Na₂O]” is preferably from 0.0 to 1.8. From the viewpoint of increasing compressive stress in the vicinity of the glass surface and easily obtaining the chemically strengthened glass with higher bending strength, the [K₂O]/[Na₂O] is more preferably 0.1 or higher, still more preferably 0.2 or higher. From the above viewpoint, the [K₂O]/[Na₂O] is more preferably 1.0 or lower, still more preferably 0.9 or lower, yet more preferably 0.8 or lower, particularly preferably 0.7 or lower.

The value given by [Al₂O₃]−[Na₂O]−[K₂O]+[Li₂O] is preferably from 10.0 to 22.0, more preferably from 10.0 to 20.0, still more preferably from 12.0 to 18.0.

MgO may be contained to lower the viscosity of glass during melting or the like. The content of MgO is more preferably 0.05% or more, more preferably in the following order: 0.1% or more; 0.2% or more; 0.9% or more; more than 0.9%; and 1.0% or more.

On the other hand, from the viewpoint of easily forming a larger compressive stress layer during chemical strengthening treatment, the content of MgO is more preferably 8.0% or less, still more preferably in the following order: 7.5% or less; 5.0% or less; 4.0% or less; and 3.8% or less. When the content of MgO is controlled to 4.0% or less, improved oxidation resistance can be obtained.

Furthermore, it is possible by containing MgO to suppress transition of the crystal phase from β-quartz solid solution to β-spodumene and suppress precipitation of β-spodumene crystals. It is thus preferable in the first embodiment that MgO is contained. From the above viewpoint, MgO is preferably contained in an amount of more than 0.5% and 7.0% or less. The further preferable ranges are as described above.

CaO is a component for improving the meltability of glass, and may be contained. The content of CaO is more preferably 0.1% or more, still more preferably 0.15% or more. On the other hand, the content of CaO is more preferably 2.0% or less, still more preferably 1.0% or less, particularly preferably 0.8% or less, most preferably 0.5% or less, from the viewpoint of easily obtaining a higher compressive stress value during chemical strengthening treatment.

With a view to achieving higher glass stability, it is preferable that at least one of MgO and CaO is contained; and it is more preferable that MgO is contained. The total content of MgO and CaO is preferably more than 0.1%, more preferably 0.2% or more, still more preferably 0.5% or more. From the viewpoint of further improvement of chemical strengthening properties, the total content of MgO and CaO is preferably 10.0% or less, more preferably in the following order: 5.0% or less; and 3.5% or less.

SrO is a component for improving the meltability of glass, and may be contained. The content of SrO is more preferably 0.1% or more, still more preferably 0.15% or more, particularly preferably 0.5% or more.

From the viewpoint of easily obtaining a higher compressive stress value during chemical strengthening treatment, the content of SrO is more preferably 3.0% or less, still more preferably 2.0% or less, particularly preferably 1.0% or less, most preferably 0.5% or less.

The glass may be substantially free of SrO.

BaO is a component for improving the meltability of glass, and may be contained. When BaO is contained, the content of BaO is preferably 0.1% or more, more preferably 0.15% or more, still more preferably 0.5% or more.

From the viewpoint of easily obtaining a higher compressive stress value during chemical strengthening treatment, the content of BaO is preferably 3.0% or less, more preferably 2.0% or less, still more preferably 1.0% or less, particularly preferably 0.5% or less.

The glass may be substantially free of BaO.

ZnO is a component for improving the meltability of the glass. The content of ZnO is more preferably 0.1% or more, still more preferably 0.15% or more, particularly preferably 0.5% or more.

From the viewpoint of easily obtaining a higher compressive stress value during chemical strengthening treatment, the content of ZnO is more preferably 3.0% or less, still more preferably 2.0% or less, particularly preferably 1.0% or less, most preferably 0.5% or less.

The glass may be substantially free of ZnO.

InW is a parameter indicating the degree of mixing of oxides, which is calculated from the contents of alkali metal oxides, alkaline earth metal oxides and zinc oxide. Here, InW is given by the following formula (W1).

$$lnW = ln ( ( [ {Li}_{2} O ] + [ {Na}_{2} O ] + [ {K}_{2} O ] + [ MgO ] + [ CaO ] + [ SrO ] + [ BaO ] + [ ZnO ] ) ! / ( [ {Li}_{2} O ] ! \times [ {Na}_{2} O ] ! \times [ MgO ] ! \times [ CaO ] ! \times [ SrO ] ! \times [ BaO ] ! \times [ ZnO ] ! ) )$$

In the formula (W1), [Li₂O], [Na₂O], [K₂O], [MgO], [CaO], [SrO], [BaO] and [ZnO] represent the contents of Li₂O, Na₂O, K₂O, MgO, CaO, SrO, BaO and ZnO, respectively, in mole percentage on the oxide basis.

Further, ! represents the factorial of a positive integer. For example, [XO]! means that the numerical value of the content of a component XO, as expressed in mole percentage on the oxide basis, is rounded to the nearest integer by discarding the decimal point, and then, the factorial of the rounded integer is calculated. Taking the Na²O content of 4.8 mol % as an example, [Na₂O]! means to calculate the factorial of “4”, which is 4×3×2×1.

The greater the value of InW, the higher the degree of mixing of the metal oxides, whereby devitrification of the glass can be suppressed accordingly. From this viewpoint, the value of InW is preferably 10 or greater, more preferably 12 or greater, still more preferably 13 or greater, particularly preferably 14 or greater. The value of InW is preferably 20 or less, more preferably 18 or less, still more preferably 17 or less.

TiO₂ is a component that has a high effect of suppressing solarization of glass, and may be contained. When TiO₂ is contained, the content of TiO₂ is preferably 0.02% or more, more preferably 0.03% or more, still more preferably 0.04% or more, particularly preferably 0.05% or more, most preferably 0.06% or more.

On the other hand, the content of TiO₂ is preferably 2.0% or less, more preferably 1.0% or less, still more preferably 0.5% or less, particularly preferably 0.25% or less, most preferably 0.15% or less, from the viewpoint of preventing a quality deterioration of the chemically strengthened glass due to devitrification.

The glass may be substantially free of TiO₂.

ZrO₂ is a component for easily increasing surface compressive stress in chemically strengthened crystallized glass. The content of ZrO₂ is more preferably more than 0%, still more preferably in the following order: 0.1% or more; 0.15% or more; 0.2% or more; 0.25% or more; 0.3% or more; and 0.4% or more.

On the other hand, from the viewpoint of suppressing the occurrence of devitrification defects and easily increasing compressive stress during chemical strengthening treatment, the content of ZrO₂ is more preferably 2.0% or less, still more preferably 1.5% or less.

P₂O₅ is a component for easily forming a larger compressive stress layer during chemical strengthening. The content of P₂O₅ is more preferably 0.5% or more, still more preferably 1.0% or more, particularly preferably 2.0% or more.

On the other hand, the content of P₂O₅ is more preferably 4.0% or less, still more preferably 2.0% or more, with a view to achieving higher oxidation resistance. From the viewpoint of preventing the occurrence of striae during glass melting, it is also preferable that the glass is substantially free if P₂O₅.

B₂O₃ is a component for improving the crack resistance of glass by reducing the brittleness of the glass, or for improving the meltability of glass. The content of B₂O₃ is more preferably 0.5% or more, more preferably 1.0% or more, still more preferably 2.0% or more.

On the other hand, the content of B₂O₃ is preferably 8.0% or less with a view to maintaining good acid resistance. The content of B₂O₃ is more preferably 6.0% or less, still more preferably 4.0% or less, particularly preferably 2.0% or less. From the viewpoint of preventing the occurrence of striae during glass melting, it is also preferable that the glass is substantially free of B₂O₃.

Y₂O₃ is a component for lowering the degree of crystal growth while easily increasing surface compressive stress in chemically strengthened crystallized glass. The content of Y₂O₃ is more preferably more than 0%, still more preferably in the following order: 0.1% or more; 0.2% or more; and 0.5% or more. On the other hand, the content of Y₂O₃ is more preferably 2.0% or less, still more preferably 1.5% or less, from the viewpoint of easily forming a larger compressive stress layer during chemical strengthening treatment.

With a view to improvement of initial solubility, the total content of ZrO₂ and Y₂O₃ is preferably 4.0% or less, more preferably 2.4% or less. The lower limit of the total content of ZrO₂ and Y₂O₃ is not particularly limited, and is preferably 0.5% or more, more preferably in the following order: 0.7% or more, 1.0% or more; and 1.2% or more, with a view to achieving higher glass strength.

The ratio of the content of ZrO₂ to the total content of ZrO₂ and Y₂O₃ (hereinafter also referred to as [ZrO₂]/([ZrO₂]+[Y₂O₃]) is more preferably 0.10 or higher, still more preferably 0.20 or higher, particularly preferably 0.25 or higher. The [ZrO₂]/([ZrO₂]+[Y₂O₃]) is more preferably 0.90 or lower, still more preferably 0.80 or lower, particularly preferably 0.75 or lower.

Although each of ZrO₂ and Y₂O₃ is known to act as a nucleating agent when used alone, the combined use of ZrO₂ and Y₂O₃ causes formation of a eutectic of ZrO₂ and Y₂O₃ so that it is possible to control devitrification temperature, crystal growth rate and crystallization start temperature.

By controlling the [ZrO₂]/([ZrO₂]+[Y₂O₃]) to within the above range, the diffusion of ions in the glass can be suppressed to suppress an increase of devitrification temperature and prevent devitrification.

By controlling the [ZrO₂]/([ZrO₂]+[Y₂O₃]) to within the above range, the glass is stabilized; and the temperature region in which nucleation proceeds and the temperature region in which crystal growth proceeds are separated with no overlap to thereby suppress an increase of crystal growth rate and prevent the occurrence of defects.

Furthermore, by controlling the [ZrO₂]/([ZrO₂]+[Y₂O₃]) to within the above range, the temperature region in which nucleation proceeds can be shifted to a low temperature side to suppress a decrease of crystallization start temperature and achieve improved production characteristics.

From the viewpoint of reducing defects in the glass, the value given by 100×[ZrO₂]+63×[Y₂O₃] is preferably 250 or smaller, more preferably 180 or smaller, still more preferably 175 or smaller, yet more preferably 170 or smaller, particularly preferably 165 or smaller. The lower limit of the value given by 100×[ZrO₂]+63×[Y₂O₃] is not particularly limited, and is preferably 100 or greater, more preferably 110 or greater, still more preferably 125 or greater, particularly preferably 130 or greater, from the viewpoint of promoting nucleation.

La₂O₃ is not an essential component, but can be contained for the same reasons as Y₂O₃. The content of La₂O₃ is preferably 0.1% or more, more preferably 0.2% or more, still more preferably 0.5% or more, particularly preferably 0.8% or more. Since too much content of La₂O₃ makes it difficult to form a larger compressive stress layer during chemical strengthening treatment, the content of La₂O₃ is preferably 5.0% or less, more preferably 3.0% or less, still more preferably 2.0% or less, particularly preferably 1.5% or less.

It is also preferable that the glass is substantially free of La₂O₃.

Nb₂O₅, Ta₂O₅, Gd₂O₃ and CeO₂ are components that have the effect of suppressing solarization of glass and improving the meltability of glass, and may be contained. The content of each of Nb₂O₅, Ta₂O₅, Gd₂O₃ and CeO₂, when contained, is preferably 0.03% or more, more preferably 0.1% or more, still more preferably 0.5% or more, particularly preferably 0.8% or more, most preferably 1.0% or more. On the other hand, the content of each of Nb₂O₅, Ta₂O₅, Gd₂O₃ and CeO₂ is preferably 3.0% or less, more preferably 2.0% or less, still more preferably 1.0% or less.

Fe₂O₃ is capable of absorbing heat ray and thus is effective in improving glass meltability. In the case of mass-production of the glass by the use of a large melting furnace, it is preferable that Fe₂O₃ is contained. In such a case, the content of Fe₂O₃ in mass % on the oxide basis is preferably 0.002% or more, more preferably 0.005% or more, still more preferably 0.007% or more, particularly preferably 0.01% or more. On the other hand, too much content of Fe₂O₃ leads to glass coloring. From the viewpoint of enhancing the transparency of the glass, the content of Fe₂O₃ in mass % on the oxide basis is preferably 0.3% or less, more preferably 0.04% or less, still more preferably 0.025% or less, particularly preferably 0.015% or less.

An additional coloring component may be contained within the range that does not inhibit the desired chemical strengthening properties. Suitable examples of the additional coloring component include CO₃O₄, MnO₂, NiO, CuO, Cr₂O₃, V₂O₅, Bi₂O₃, SeO₂, Er₂O₃ and Nd₂O₃.

As a fining agent in melting of the glass, SO₃, a chloride, a fluoride or the like may be contained as appropriate. It is preferred that As₂O₃ is not contained. When Sb₂O₃ is contained, the content of Sb₂O₃ is preferably 0.3% or less, more preferably 0.1% or less. Most preferably, Sb₂O₃ is not contained.

From the viewpoint of (re)fining of bubbles in the glass, the content of SnO₂ is preferably 0.1% or more, more preferably 0.2% or more, particularly preferably 0.3% or more. From the viewpoint of suppressing the occurrence of defects, the content of SnO₂ is preferably 1% or less, more preferably 0.8% or less, still more preferably 0.7% or less, particularly preferably 0.5% or less.

The preferable physical properties of the glass having the base glass composition of the first embodiment will next be described below.

### (Devitrification Temperature)

In the case of the glass for chemical strengthening having the base glass composition of the first embodiment, the devitrification temperature is preferably 1300° C. or lower. The devitrification temperature is more preferably 1280° C. or lower, still more preferably 1250° C. or lower, particularly preferably in the following order: 1240° C. or lower; 1230° C. or lower; 1220° C. or lower; and 1210° C. or lower. The lower limit of the devitrification temperature is not particularly limited, and is usually 1100° C. or higher.

When the devitrification temperature of the glass for chemical strengthening is 1300° C. or lower (preferably 1280° C. or lower), the glass can be formed stably and improved in production characteristics. More specifically, the forming of glass by a float method may cause, when crystals are formed before pouring of a molten glass into a float bath, erosion of brick constituting the float bath by the crystals. Such brick erosion can be prevented when the devitrification temperature of the glass for chemical strengthening is 1300° C. or lower (preferably 1280° C. or lower).

Here, the devitrification temperature of glass refers to a minimum value of temperature at which, after crushed glass particles having a size of 2 to 3 mm are put in a platinum dish and heat-treated for 17 hours by an electric furnace controlled at a constant temperature, precipitated crystals on the glass surface and inside the glass are not observed by an optical microscope.

### (Glass Transition Temperature Tg, Crystallization Start Temperature Tcs and Crystallization Peak Temperature Tc)

In the present specification, the differential scanning calorimetry (DSC) measurement of glass is carried out by grinding glass in an agate mortar to obtain a glass powder with a particle size of 106 to 180 μm and heating about 70 mg of the glass powder from room temperature to 1200° C. at a temperature rise rate of 10° C./min.

In the case of the glass for chemical strengthening having the base glass composition of the first embodiment, the crystallization start temperature Tcs as measured by DSC is preferably 790° C. or higher, more preferably 800° C. or higher, still more preferably 810° C. or higher, yet more preferably 815° C. or higher, particularly preferably 820° C. or higher, most preferably 825° C. or higher. The upper limit of the crystallization start temperature Tcs is not particularly limited, and is usually 900° C. or lower.

When the crystallization start temperature Tcs is 790° C. or higher, the glass can be improved in production characteristics. More specifically, for example, the forming of glass including forming into a three-dimensional shape to be heat-treated after forming into a sheet shape (for example, 2.5D or 3D forming; hereinafter also referred to as three-dimensional forming) is likely to cause defects due to crystallization as the glass passes through its nucleation temperature during the temperature rise from room temperature to a forming temperature. When the crystallization start temperature Tcs is 790° C. or higher, the glass can be formed without passing through the nucleation temperature during the temperature rise from room temperature to the forming temperature, and thus, the occurrence of defects can be suppressed.

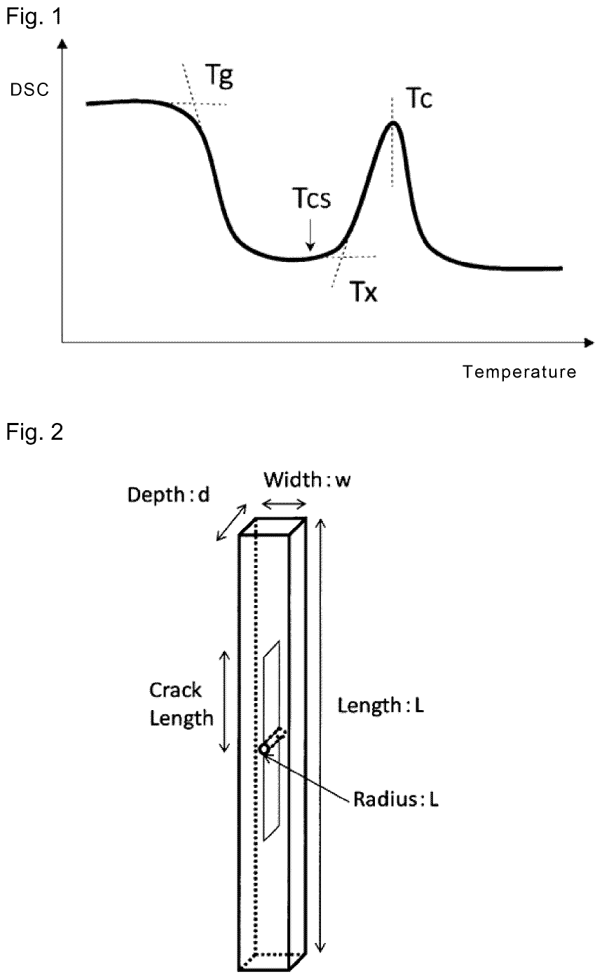

FIG. 1 is a schematic view for explaining Tg, Tcs and Tc in the present specification. In the present specification, the glass transition temperature Tg is defined as a point of intersections of auxiliary lines on a shift of baseline in the DSC curve as shown in FIG. 1. Further, the crystallization start temperature Tcs is defined as an exothermic peak point of the DSC curve during temperature rise of the glass at 10° C./min.

In the case of the glass for chemical strengthening having the base glass composition of the first embodiment, the ratio of the crystallization start temperature Tcs to the glass transition temperature Tg as given by (Tcs+273.15)/(Tg+273.15) is preferably 1.10 or higher, more preferably 1.15 or higher, still more preferably 1.20 or higher, particularly preferably 1.25 or higher. By controlling the ratio (Tcs+273.15)/(Tg+273.15) to 1.10 or higher, the glass can be prevented from the occurrence of defects during three-dimensional forming and improved in forming properties. The upper limit of the ratio (Tcs+273.15)/(Tg+273.15) is not particularly limited, and is usually 1.6 or lower in terms of the formability of the glass. In the ratio (Tcs+273.15)/(Tg+273.15), the temperature Tcs and the temperature Tg are in units of ° C. The value of “(Tcs+273.15)/(Tg+273.15)” equals to the value of “Tcs/Tg” where both of Tcs and Tg are in units of K.

In the case of the glass for chemical strengthening having the base glass composition of the first embodiment, the value (Tcs-Tg) obtained by subtracting the glass transition temperature Tg from the crystallization start temperature Tcs is preferably 180° C. or more, more preferably 200° C. or more, still more preferably 210° C. or more, yet more preferably 215° C. or more, particularly preferably 225° C. or more, most preferably 230° C. or more. When the value (Tcs-Tg) is 180° C. or more, the glass can be prevented from the occurrence of defects during three-dimensional forming and improved in forming properties. The upper limit of the value (Tcs-Tg) is not particularly limited, and is usually preferably 400° C. or less in terms of the formability of the glass.

From the viewpoint of reducing warpage of the glass after the chemical strengthening, the glass transition temperature Tg is preferably 500° C. or higher, more preferably 520° C. or higher, still more preferably 540° C. or higher. From the viewpoint of ease of float forming, the glass transition temperature Tg is preferably 750° C. or lower, more preferably 700° C. or lower, still more preferably 650° C. or lower, particularly preferably 600° C. or lower, most preferably 580° C. or lower.

In the case of the glass for chemical strengthening having the base glass composition of the first embodiment, the crystallization peak temperature Tc is preferably 790° C. or higher, more preferably 800° C. or higher, still more preferably 810° C. or higher. When the crystallization peak temperature Tc is 790° C. or higher, stable forming of the glass can be achieved. It is most preferable that no crystallization peak is observed. The upper limit of the crystallization peak temperature Tc is not particularly limited, and is usually 950° C. or lower.

### (Crystal Growth Rate)

In the case of the glass for chemical strengthening having the base glass composition of the first embodiment, it is possible by containing MgO to suppress transition of the crystal phase from β-quartz solid solution to β-spodumene and suppress precipitation of β-spodumene crystals. Accordingly, precipitation of β-spodumene can be suppressed even when the glass for chemical strengthening is held at 1000° C. for 30 minutes. Further, the rate of crystal growth can also be lowered.

When MgO is contained in the base glass composition of the first embodiment, the first precipitated phase of the glass for chemical strengthening preferably consists of 3-quartz solid solution; and the rate of crystal growth of β-quartz solid solution at 1000° C. in the glass for chemical strengthening is preferably 4000 μm/hr or lower, more preferably 3800 μm/hr or lower, still more preferably 3500 μm/hr or lower, particularly preferably 3200 μm/hr or lower, most preferably 2700 μm/hr or lower.

In a forming process of glass, the occurrence of crystallization causes defects in the glass. For example, in the forming of glass by a float method using a float bath, as the inside of the float bath is cooled from high temperature areas, crystallization occurs in an overlap portion of the float bath between the temperature region in which nucleation proceeds and the temperature region in which crystal growth proceeds.

Ordinary glass has no overlap between the temperature region in which nucleation proceeds and the temperature region in which crystal growth proceeds. On the other hand, glass with high contents of Al₂O₃ and Li₂O tends to have, at or around 1000° C., an overlap between the temperature region in which nucleation proceeds and the temperature region in which crystal growth proceeds. The overlap between the temperature region in which nucleation proceeds and the temperature region in which crystal growth proceeds would not become a drawback when the rate of crystal growth is low. Therefore, crystallization during the forming process can be suppressed by limiting the rate of crystal growth of β-quartz solid solution at 1000° C. to 600 μm/hr or lower.

In the present specification, the rate of crystal growth of β-quartz solid solution at 1000° C. is determined by holding a glass sample at 1000° C. for 30 minutes, measuring the lengths of crystals in the glass sample by a polarized optical microscope and taking an average value of the measured crystal lengths. The rate of crystal growth of β-spodumene at 1000° C. is determined by the same method as above.

Furthermore, the “β-OH value” of glass is determined according to the following formula:

$$β - OH value = ( 1 / t ) {log}_{10} ( {X}_{1} / {X}_{2} )$$

where X₁ represents the transmittance (%) of the glass as measured at a reference wavelength of 4000 cm⁻¹ by the FT-IR method; X₂ represents the minimum transmittance (%) of the glass as measured by the FT-IR method in the vicinity of 3570 cm⁻¹, which is an absorption wavelength of hydroxyl groups; and t represents the sheet thickness (unit: mm) of the glass.

Here, the β-OH value can be adjusted according to the water content and melting conditions of raw glass material.

In the case of the glass for chemical strengthening having the base glass composition of the first embodiment, the β-OH value is preferably 0.1 mm⁻¹ or higher, more preferably 0.15 mm⁻¹ or higher, still more preferably 0.2 mm⁻¹ or higher, particularly preferably 0.22 mm⁻¹ or higher, most preferably 0.25 mm⁻¹ or higher.

The β-OH value is an index for the content of water in glass. Glass with a higher 1-OH value has a lower softening point and tends to be easier to bend. On the other hand, from the viewpoint of strength improvement of glass by chemical strengthening, the surface compressive stress (CS) of glass after chemical strengthening tends to be lower as the glass has a higher β-OH value. From the above viewpoints, the β-OH value is preferably 0.5 mm⁻¹ or lower, more preferably 0.4 mm⁻¹ or lower, still more preferably 0.3 mm⁻¹ or lower.

In the case of the glass for chemical strengthening having the base glass composition of the first embodiment, the ratio of Na_DOL to K_DOL as defined below (hereinafter also referred to as “Na_DOL/K_DOL”) is preferably 26 or lower, more preferably in the following order: 25 or lower; 24 or lower; 23 or lower; 22 or lower; 21 or lower; and 20 or lower, from the viewpoint of ease of improvement in the drop strength of the glass by the later-described preferable embodiment of chemical strengthening treatment (more specifically, after the first stage of chemical strengthening treatment with the Na salt, introducing K into the glass during the second stage of chemical strengthening treatment with a mixed Li/K salt as will be described later).

From the viewpoint of preventing breakage of the glass by preventing excessive introduction of K into the glass during the second stage of chemical strengthening treatment with the mixed Li/K salt after the first stage of chemical strengthening treatment with the Na salt, the ratio Na_DOL/K_DOL is preferably 15 or higher, more preferably in the following order: 16 or higher; 16.5 or higher; 17 or higher; 17.5 or higher; and 18 or higher.
K_DOL: Depth of compressive stress layer formed by chemical strengthening of glass through ion exchange treatment with a molten salt of 100% potassium nitrate
Na_DOL: Depth of compressive stress layer formed by chemical strengthening of glass through ion exchange treatment with a molten salt of 100% sodium nitrate
Here, the time and temperature conditions of the ion exchange treatments for determination of K_DOL and Na_DOL are set to the same conditions.

In the case of the glass for chemically strengthening having the base glass composition of the first embodiment, the fracture toughness value K_{IC} is preferably 0.70 MPa·m^{1/2} or higher, more preferably 0.75 MPa·m^{1/2} or higher, still more preferably 0.80 MPa·m^{1/2} or higher. The upper limit of the fracture toughness value K_{IC} is not particularly limited, and is typically 1.0 MPa·m^{1/2} or lower.

In the case of the glass for chemical strengthening having the base glass composition of the first embodiment, the Young's modulus is preferably 80 GPa or higher, more preferably 85 GPa or higher, still more preferably 90 GPa or higher, particularly preferably 95 GPa or higher. The upper limit of the Young's modulus is not particularly limited, and is typically 120 GPa or lower.

### Second Embodiment

The base glass composition of the second embodiment includes, in mole percentage on the oxide basis,
55 to 75% of SiO₂,
3 to 18% of Al₂O₃,
17 to 30% of Li₂O,
0 to 3% of Na₂O,
0 to 1% of K₂O,
0 to 10% of MgO,
0 to 10% of CaO,
0 to 5% of SrO,
0 to 5% of ZnO,
0 to 3% of TiO₂,
0 to 5% of ZrO₂,
0 to 1% of SnO₂,
0 to 3% of P₂O₅,
0 to 10% of B₂O₃, and
0 to 3% of Y₂O₃.

It is particularly preferable that the base glass composition of the second embodiment includes, in mole percentage on the oxide basis,
55 to 75% of SiO₂,
3 to 18% of Al₂O₃,
17 to 30% of Li₂O,
0 to 3% of Na₂O,
0 to 1% of K₂O,
0 to 10% of MgO,
0 to 10% of CaO,
0 to 5% of SrO,
0 to 5% of ZnO,
0 to 3% of TiO₂,
0 to 5% of ZrO₂,
0 to 1% of SnO₂,
0 to 3% of P₂O₅,
0 to 10% of B₂O₃, and
0 to 3% of Y₂O₃,
   wherein the sum of the content of Li₂O, the content of Na₂O and the content of K₂O, referred to as the total content R, is from 8 to 35%; the ratio of the content of Li₂O to the total content R is from 0.85 to 0.99; and the product of the ratio of the content of Li₂O to the total content R, the ratio of the content of Na₂O to the total content and the ratio of the content of K₂O to the total content R is from 0 to 0.003.

The respective components of the base glass composition of the second embodiment will be described in more detail below.

SiO₂ is a component for forming a network structure in glass. SiO₂ is also a component for improving the chemical resistance of glass and a component for suppressing the occurrence of cracks in glass due to scratches caused on a surface of the glass.

With a view to improvement of chemical resistance, the content of SiO₂ is more preferably 57.0% or more, still more preferably 58.0% or more, particularly preferably 59.0% or more, most preferably 60.0% or more. On the other hand, the content of SiO₂ is more preferably 74.0% or less, still more preferably 72.0% or less, particularly preferably 69.0% or less, with a view to obtaining good meltability.

Al₂O₃ is a component for improving the ion exchange performance of glass during chemical strengthening to increase surface compressive stress in the glass after the chemical strengthening. Further, Al₂O₃ contributes to the formation of crystals containing Al and Li.

From the viewpoint of obtaining the above effects, the content of Al₂O₃ is more preferably 3.5% or more, still more preferably in the following order: 4.0% or more; and 4.3% or more. On the other hand, it may be required that: crystals are difficult to grow during melting of the glass; devitrification defects are less likely to occur in the glass, thereby easily achieving a higher yield; or the glass is made lower in high-temperature viscosity and easier to melt. From such viewpoints, the content of Al₂O₃ is more preferably 18.0% or less, still more preferably in the following order: 15.0% or less; 12.0% or less; 9.0% or less; 7.0% or less; and 6.0% or less.

Each of SiO₂ and Al₂O₃ acts to stabilize the structure of glass. The total content of SiO₂ and Al₂O₃ is preferably 60.0% or more, more preferably 62.0% or more, still more preferably 64.0% or more, with a view to reduction of brittleness.

Further, each of SiO₂ and Al₂O₃ tends to raise the melting temperature of glass. From the viewpoint of ease of glass melting, the total content of SiO₂ and Al₂O₃ is preferably 80.0% or less, more preferably 75.0% or less, still more preferably 74.0% or less.

Li₂O is a component capable of ion exchange reaction and is a component for improving the meltability of glass. When Li₂O is contained in glass, a stress profile with higher surface compressive stress and thick compressive stress layer is easily obtained by exchanging Li ions on the glass surface with external Na ions to introduce Na ions to the inside of the glass and then exchanging the introduced Na ions with external K ions.

Furthermore, the glass is easily obtained in the form of crystallized glass by specific heat treatment when the content of Li₂O is in the above range. From such viewpoints, the content of Li₂O is more preferably 17% or more, still more preferably in the following order: 18% or more; 19% or more; and 20% or more.

On the other hand, from the viewpoint of lowering the rate of crystal growth during glass forming and suppressing a deterioration of quality due to devitrification, the content of Li₂O is more preferably 30% or less, still more preferably in the following order: 28% or less; 26% or less; 24% or less; and 23% or less.

Na₂O and K₂O are components for improving the meltability of glass and lowering the rate of crystal growth during glass forming. With a view to not only obtaining these effects but also improving the ion exchange performance of the glass, it is preferable that Na₂O and K₂O are contained in small amounts.

Na₂O is a component capable of ion exchange rection during chemical strengthening treatment with a potassium salt, and is a component for lowering the viscosity of glass. From the viewpoint of obtaining the above effects, the content of Na₂O is preferably 0.3% or more, more preferably in the following order: 0.5% or more; 0.8% or more; 1.0% or more; 1.2% or more; and 1.5% or more. On the other hand, the content of Na₂O is preferably 3.0% or less, more preferably 2.5% or less, still more preferably 2.3% or less, from the viewpoint of maintaining glass network and avoiding a decrease of surface compressive stress (Na_CS) by strengthening treatment with a sodium salt.

K₂O is a component for suppressing devitrification by suppressing an increase of devitrification temperature and for improving the ion exchange performance of glass. The content of K₂O is more preferably 0.1% or more, still more preferably 0.15% or more, particularly preferably 0.2% or more, most preferably 0.5% or more.

On the other hand, the content of K₂O is more preferably 1.0% or less, more preferably 0.8% or less, from the viewpoint of avoiding a decrease of surface compressive stress (K_CS) by strengthening treatment with a sodium salt.

Here, the glass may be substantially free of K₂O.

The sum of the content of Li₂O, the content of Na₂O and the content of K₂O, referred to as the total content R is more preferably from 10 to 30%, still more preferably 15 to 28%, particularly preferably 18 to 25%, from the viewpoint of suppressing an increase of devitrification temperature and lowering the rate of crystal growth.

The ratio of the content of Li₂O to the total content R ([Li₂O]/([Li₂O]+[Na₂O]+[K₂O]; hereinafter also referred to as “Li₂O/R₂O”) is more preferably 0.88 or higher, still more preferably 0.90 or higher, from the viewpoint of further improvement of chemical strengthening properties in terms of compressive stress in a deeper layer portion of the glass. With a view to achieving higher glass electrical resistance and higher chemical resistance, the Li₂O/R₂O is preferably 0.98 or lower, more preferably 0.95 or lower, particularly preferably 0.94 or lower.

The ratio of the content of Na₂O to the total content R ([Na₂O]/([Li₂O]+[Na₂O]+[K₂O]; hereinafter also referred to as “Na₂O/R₂O”) is preferably higher than 0, more preferably 0.01 or higher, still more preferably 0.03 or higher, particularly preferably 0.05 or higher, most preferably 0.06 or higher. The Na₂O/R₂O is preferably 0.40 or lower, more preferably 0.30 or lower, still more preferably 0.20 or lower, particularly preferably 0.10 or lower, with a view to achieving higher chemical resistance.

The ratio of the content of K₂O to the total content R ([K₂O]/([Li₂O]+[Na₂O]+[K₂O]; hereinafter also referred to as “K₂O/R₂O”) is preferably 0.05 or higher, more preferably 0.08 or higher, still more preferably 0.10 or higher, with a view to achieving higher glass electrical resistance. The K₂O/R₂O is preferably 0.50 or lower, more preferably 0.40 or lower, still more preferably 0.30 or lower, particularly preferably 0.20 or lower, from the viewpoint of further improvement of chemical strengthening properties in terms of compressive stress in the vicinity of the glass surface.

Here, the K₂O/R₂O may be zero.

Further, the product of the Li₂O/R₂O, the Na₂O/R₂O and the K₂O/R₂O is preferably 0.008 or higher, more preferably 0.01 or higher, particularly preferably 0.02 or higher, from the viewpoint of suppressing an increase of devitrification temperature and lowering the rate of crystal growth. Further, the above product is more preferably 0.028 or lower.

Here, the above product may be zero.

The ratio of the content of Al₂O₃ to the total content R ([Al₂O₃]/([Li₂O]+[Na₂O]+[K₂O]); hereinafter also referred to as “Al₂O₃/R₂O”) is preferably 0.05 or higher, more preferably 0.10 or higher, still more preferably 0.15 or higher, particularly preferably 0.18 or higher. The Al₂O₃/R₂O is preferably 0.50 or lower, more preferably 0.40 or lower, still more preferably 0.30 or lower, particularly preferably 0.25 or lower.

The value given by [Al₂O₃]−[Na₂O]−[K₂O]+[Li₂O] is preferably from 15.0 to 35.0%, more preferably from 20.0 to 30.0%.

MgO may be contained to lower the viscosity of glass during melting or the like. The content of MgO is more preferably 0.05% or more, still more preferably in the following order: 0.5% or more; 1.0% or more; 2.0% or more; 3.0% or more; and 4.0% or more.

On the other hand, from the viewpoint of easily forming a larger compressive stress layer during chemical strengthening treatment, the content of MgO is more preferably 9.0% or less, still more preferably in the following order: 8.0% or less; 7.0% or less; and 6.0% or less.

Furthermore, it is possible by containing MgO to suppress transition of the crystal phase from β-quartz solid solution to β-spodumene and suppress deposition of 3-spodumene crystals. It is thus preferable in the second embodiment that MgO is contained. From the above viewpoint, MgO is preferably contained in an amount of more than 0.5% and 7.0% or less. The further preferable ranges are as mentioned above.

The glass may be substantially free of MgO.

CaO is a component for improving the meltability of glass and may be contained. The content of CaO is more preferably 0.1% or more, still more preferably 0.15% or more. On the other hand, the content of CaO is more preferably 2.0% or less, still more preferably 1.0% or less, particularly preferably 0.8% or less, most preferably 0.5% or less, from the viewpoint of easily obtaining a higher compressive stress value during chemical strengthening treatment.

The glass may be substantially free of CaO.

With a view to achieving higher glass stability, it is preferable that at least one of MgO and CaO is contained; and it is more preferable that MgO is contained. The total content of MgO and CaO is preferably more than 1.0%, more preferably 2.0% or more, still more preferably 3.0% or more, particularly preferably 4.0% or more. From the viewpoint of further improvement of chemical strengthening properties, the total content of MgO and CaO is preferably 10.0% or less, more preferably in the following order: 8.0% or less; 7.0% or less; and 6.0% or less.

SrO is a component for improving the meltability of glass and may be contained. The content of SrO is more preferably 0.1% or more, still more preferably 0.15% or more, particularly preferably 0.5% or more.

From the viewpoint of easily obtaining a higher compressive stress value during chemical strengthening treatment, the content of SrO is more preferably 3.0% or less, still more preferably 2.0% or less, particularly preferably 1.0% or less, most preferably 0.5% or less.

The glass may be substantially free of SrO.

BaO is a component for improving the meltability of glass and may be contained. When BaO is contained, the content of BaO is preferably 0.1% or more, more preferably 0.15% or more, still more preferably 0.5% or more.

From the viewpoint of easily obtaining a higher compressive stress value during chemical strengthening treatment, the content of BaO is preferably 3.0% or less, more preferably 2.0% or less, still more preferably 1.0% or less, particularly preferably 0.5% or less.

The glass may be substantially free of BaO.

ZnO is a component for improving the meltability of the glass. The content of ZnO is more preferably 0.1% or more, still more preferably 0.15% or more, particularly preferably 0.5% or more.

From the viewpoint of easily obtaining a higher compressive stress value during chemical strengthening treatment, the content of ZnO is more preferably 3.0% or less, still more preferably 2.0% or less, particularly preferably 1.0% or less, most preferably 0.5% or less.

The glass may be substantially free of ZnO.

InW is a parameter indicating the degree of mixing of oxides, which is calculated from the contents of alkali metal oxides, alkaline earth metal oxides and zinc oxide. Here, InW is given by the following formula (W1).

$$( W 1 )$$

$$lnW = ln ( ( [ {Li}_{2} O ] + [ {Na}_{2} O ] + [ {K}_{2} O ] + [ MgO ] + [ CaO ] + [ SrO ] + [ BaO ] + [ ZnO ] ) ! / ( [ {Li}_{2} O ] ! \times [ {Na}_{2} O ] ! \times [ {K}_{2} O ] ! \times [ MgO ] ! \times [ CaO ] ! \times [ SrO ] ! \times [ B aO ] ! \times [ ZnO ] ! ) )$$

In the formula (W1), [Li₂O], [Na₂O], [K₂O], [MgO], [CaO], [SrO], [BaO] and [ZnO] represent the contents of Li₂O, Na₂O, K₂O, MgO, CaO, SrO, BaO and ZnO, respectively, in mole percentage on the oxide basis.

Further, ! represents the factorial of a positive integer. For example, [XO]! means that the numerical value of the content of a component XO, as expressed in mole percentage on the oxide basis, is rounded to the nearest integer by discarding the decimal point, and then, the factorial of the rounded integer is calculated. Taking the Na₂O content of 4.8 mol % as an example, [Na₂O]! means to calculate the factorial of “4”, which is 4×3×2×1.

The greater the value of InW, the higher the degree of mixing of the metal oxides, whereby devitrification of the glass can be suppressed accordingly. From this viewpoint, the value of InW is preferably 10 or greater, more preferably 12 or greater, still more preferably 13 or greater, particularly preferably 14 or greater. The value of InW is preferably 20 or less, more preferably 18 or less, still more preferably 17 or less.

TiO₂ is a component that has a high effect of suppressing solarization of glass and is a material that forms nuclei of crystals. Thus, TiO₂ may be contained. When TiO₂ is contained, the content of TiO₂ is preferably 0.05% or more, more preferably 0.1% or more, still more preferably 0.2% or more, particularly preferably 0.5% or more, most preferably 0.8% or more.

On the other hand, in view of the fact that TiO₂ has light absorption properties, the content of TiO₂ is preferably 2.5% or less, more preferably 2.0% or less, still more preferably 1.5% or less, particularly preferably 1.0% or less, from the viewpoint of preventing coloring of the glass.

The glass may be substantially free of TiO₂.

ZrO₂ is a component for easily increasing surface compressive stress in chemically strengthened glass, and is also a material that forms nuclei of crystals. Thus, ZrO₂ may be contained. The content of ZrO₂ is more preferably more than 0%, still more preferably in the following order: 0.5% or more; 1.0% or more; 1.5% or more; 2.0% or more; and 2.5% or more.

P₂O₅ is a component for easily forming a larger compressive stress layer during chemical strengthening. The content of P₂O₅ is more preferably 0.5% or more, still more preferably 0.7% or more.

On the other hand, the content of P₂O₅ is more preferably 2.0% or less, with a view to achieving higher acid resistance. From the viewpoint of preventing the occurrence of striae during melting, it is also be preferable that the glass is substantially free of P₂O₅.

B₂O₃ is a component for improving the crack resistance of glass by reducing the brittleness of the glass, or for improving the meltability of glass. The content of B₂O₃ is more preferably 0.5% or more, more preferably 1.0% or more, still more preferably 1.5% or more.

On the other hand, the content of B₂O₃ is preferably 8.0% or less with a view to maintaining good acid resistance. The content of B₂O₃ is more preferably 6.0% or less, still more preferably 4.0% or less, particularly preferably 2.0% or less. It is also preferable that the glass is substantially free of B₂O₃ from the viewpoint of preventing the occurrence of striae during melting.

Y₂O₃ is a component for lowering the degree of crystal growth while easily increasing surface compressive stress in chemically strengthened glass. The content of Y₂O₃ is more preferably more than 0%, still more preferably in the following order: 0.1% or more; 0.2% or more; 0.5% or more; and 0.8% or more. On the other hand, the content of Y₂O₃ is more preferably 2.0% or less, still more preferably 1.5% or less, from the viewpoint of easily forming a larger compressive stress layer during chemical strengthening treatment.

The glass may be substantially free of Y₂O₃.

With a view to improvement of initial solubility, the total content of ZrO₂ and Y₂O₃ is preferably 5.0% or less. The lower limit of the total content of ZrO₂ and Y₂O₃ is not particularly limited, and is preferably 0.5% or more, more preferably in the following order: 1.0% or more; 1.5% or more; 2.0% or more; 2.5% or more; and 3.0% or more, with a view to achieving higher glass strength.

The ratio of the content of ZrO₂ to the total content of ZrO₂ and Y₂O₃, referred to as [ZrO₂]/([ZrO₂]+[Y₂O₃]), is preferably 0.50 or higher, more preferably 1.00 or higher. The [ZrO₂]/([ZrO₂]+[Y₂O₃]) is preferably 8.00 or lower, more preferably 7.00 or lower, particularly preferably 6.00 or lower.

Although each of ZrO₂ and Y₂O₃ is known to act as a nucleating agent when used alone, the combined use of ZrO₂ and Y₂O₃ causes formation of a eutectic of ZrO₂ and Y₂O₃ so that it is possible to control devitrification temperature, crystal growth rate and crystallization start temperature.

By controlling the [ZrO₂]/([ZrO₂]+[Y₂O₃]) to within the above range, the diffusion of ions in the glass can be suppressed to suppress an increase of devitrification temperature and prevent devitrification.

By controlling the [ZrO₂]/([ZrO₂]+[Y₂O₃]) to within the above range, the glass is stabilized; and the temperature region in which nucleation proceeds and the temperature region in which crystal growth proceeds are separated with no overlap to thereby suppress an increase of crystal growth rate and prevent the occurrence of defects. Furthermore, by controlling the [ZrO₂]/([ZrO₂]+[Y₂O₃]) to within the above range, the temperature region in which nucleation proceeds can be shifted to a low temperature side to suppress a decrease of crystallization start temperature and achieve improved production characteristics.

La₂O₃ is not an essential component, but can be contained for the same reasons as Y₂O₃. The content of La₂O₃ is preferably 0.1% or more, more preferably 0.2% or more, still more preferably 0.5% or more, particularly preferably 0.8% or more. Since too much content of La₂O₃ makes it difficult to form a larger compressive stress layer during chemical strengthening treatment, the content of La₂O₃ is preferably 5.0% or less, more preferably 3.0% or less, still more preferably 2.0% or less, particularly preferably 1.5% or less.

It is also preferable that the glass is substantially free of La₂O₃.

Nb₂O₅, Ta₂O₅, Gd₂O₃ and CeO₂ are components that have the effect of suppressing solarization of glass and improving the meltability of the glass, and may be contained. The content of each of Nb₂O₅, Ta₂O₅, Gd₂O₃ and CeO₂, when contained, is preferably 0.03% or more, more preferably 0.1% or more, still more preferably 0.5% or more, particularly preferably 0.8% or more, most preferably 1.0% or more. On the other hand, the content of each of Nb₂O₅, Ta₂O₅, Gd₂O₃ and CeO₂ is preferably 3.0% or less, more preferably 2.0% or less, still more preferably 1.0% or less.

Fe₂O₃ is capable of absorbing heat ray and thus is effective in improving glass meltability. In the case of mass-production of the glass by the use of a large melting furnace, it is preferable that Fe₂O₃ is contained. In such a case, the content of Fe₂O₃ in mass % on the oxide basis is preferably 0.002% or more, more preferably 0.005% or more, still more preferably 0.007% or more, particularly preferably 0.01% or more. On the other hand, too much content of Fe₂O₃ leads to glass coloring. From the viewpoint of enhancing the transparency of the glass, the content of Fe₂O₃ in mass % on the oxide basis is preferably 0.3% or less, more preferably 0.04% or less, still more preferably 0.025% or less, particularly preferably 0.015% or less.

An additional coloring component may be contained within the range that does not inhibit the desired chemical strengthening properties. Suitable examples of the additional coloring component include CO₃O₄, MnO₂, NiO, CuO, Cr₂O₃, V₂O₅, Bi₂O₃, SeO₂, Er₂O₃ and Nd₂O₃.

As a fining agent in melting of the glass, SO₃, a chloride, a fluoride or the like may be contained as appropriate. It is preferred that As₂O₃ is not contained. When Sb₂O₃ is contained, the content of Sb₂O₃ is preferably 0.3% or less, more preferably 0.1% or less. Most preferably, Sb₂O₃ is not contained.

From the viewpoint of (re)fining of bubbles in the glass, the content of SnO₂ is preferably 0.01% or more, more preferably 0.05% or more. From the viewpoint of suppressing the occurrence of defects, the content of SnO₂ is preferably 1% or less, more preferably 0.8% or less, still more preferably 0.7% or less, particularly preferably 0.5% or less.

The preferable physical properties of the glass having the base glass composition of the second embodiment will next be described below.

### (Devitrification Temperature)

Since the preferable range of the devitrification temperature of the glass for chemical strengthening having the base glass composition of the second embodiment is the same as that of the glass for chemical strengthening having the base glass composition of the first embodiment, a description thereof will be omitted.

### (Glass Transition Temperature Tg, Crystallization Start Temperature Tcs and Crystallization Peak Temperature Tc)

In the case of the glass for chemical strengthening having the base glass composition of the second embodiment, the crystallization start temperature Tcs as measured by DSC is preferably 500° C. or higher. The upper limit of the crystallization start temperature Tcs is not particularly limited, and is usually 800° C. or lower.

When the crystallization start temperature Tcs is in the above range, the glass for chemical strengthening is obtained as crystallized glass by causing precipitation of crystals in the glass through heat treatment of holding the glass at 500 to 600° C. for 1 to 6 hours and holding the glass at 600 to 800° C. for 0.5 to 6 hours.

The heat treatment may be performed in three steps. For example, the glass for chemical strengthening can be obtained as crystallized glass by holding the glass at 500 to 600° C. for 1 to 6 hours, holding the glass at 550 to 650° C. for 0.5 to 6 hours and then holding the glass at 600 to 800° C. for 0.5 to 6 hours.

From the viewpoint of reducing warpage of the glass after chemical strengthening, the glass transition temperature Tg is preferably 500° C. or higher, more preferably 520° C. or higher, still more preferably 540° C. or higher. From the viewpoint of ease of float forming, the glass transition temperature Tg is preferably 750° C. or lower, more preferably 700° C. or lower, still more preferably 650° C. or lower, particularly preferably 600° C. or lower, most preferably 580° C. or lower.

In the case of the glass for chemical strengthening having the base glass composition of the second embodiment, the crystallization peak temperature Tc is preferably 600° C. or higher, more preferably 650° C. or higher, still more preferably 700° C. or higher. When the crystallization peak temperature Tc is 600° C. or higher, stable forming of the glass can be achieved. It is most preferable that no crystallization peak is observed. The upper limit of the crystallization peak temperature Tc is not particularly limited, and is usually 950° C. or lower.

In the case of the glass for chemical strengthening having the base glass composition of the second embodiment, the β-OH value is preferably 0.1 mm⁻¹ or higher, more preferably 0.15 mm⁻¹ or higher, still more preferably 0.2 mm⁻¹ or higher, particularly preferably 0.22 mm⁻¹ or higher, most preferably 0.25 mm⁻¹ or higher.

The β-OH value is an index for the content of water in glass. Glass with a higher β-OH value has a lower softening point and tends to be easier to bend. On the other hand, from the viewpoint of strength improvement of glass by chemical strengthening, the surface compressive stress (CS) of glass after chemical strengthening tends to be lower as the glass has a higher β-OH value. From the above viewpoints, the β-OH value is preferably 0.5 mm⁻¹ or lower, more preferably 0.4 mm⁻¹ or lower, still more preferably 0.3 mm⁻¹ or lower.

In the case of the glass for chemical strengthening having the base glass composition of the second embodiment, the fracture toughness value (K_{IC}) is preferably 0.80 MPa·m^{1/2} or higher, more preferably 0.85 MPa·m^{1/2} or higher, still more preferably 0.90 MPa·m^{1/2} or higher, particularly preferably 1.0 MPa·m^{1/2} or higher, most preferably 1.1 MPa·m^{1/2} or higher. The upper limit of the fracture toughness value K_{IC} is not particularly limited, and is typically 1.6 MPa·m^{1/2} or lower.

In the case of the glass for chemical strengthening having the base glass composition of the second embodiment, the Young's modulus is preferably 80 GPa or higher, more preferably 90 GPa or higher, still more preferably 95 GPa or higher, most preferably 100 GPa or higher. The upper limit of the Young's modulus is not particularly limited, and is typically 120 GPa or lower.

### (Production Method)

The glass for chemical strengthening (the base glass composition of the first embodiment or the base glass composition of the second embodiment) can be produced by a usual method. For example, raw materials for the respective components of the glass are mixed and melted by heating in a glass melting furnace, and then, the resulting glass is homogenized by a known method, formed into a desired shape such as sheet shape and annealed.

As the method for forming sheet glass, a float method, a press method, a fusion method and a downdraw method may be mentioned. Particularly preferred is a float method which is suitable for mass production. A continuous forming method other than the float method, such as a fusion method or a downdraw method, is also preferred.

The glass for chemical strengthening having the base glass composition of the second embodiment may be obtained as crystallized glass by the heat treatment as described above.

In other words, the glass for chemical strengthening may be in the form of crystallized glass. When crystallized glass is used as the glass for chemical strengthening, the resulting chemically strengthened glass is obtained as crystallized glass.

After that, the formed sheet glass is processed into a glass substrate etc. by grinding and polishing as necessary. In the case where the glass substrate is cut into a predetermined shape and size or is subjected to chamfering, the cutting or chamfering of the glass substrate may preferably be carried out before the later-described chemical strengthening treatment so as to form a compressive stress layer also on end faces of the glass substrate through such subsequent chemical strengthening treatment.

The glass for chemical strengthening may have a shape other than the sheet shape depending on the product to which it is applied and its intended use. The sheet glass may have a rim shape of different thicknesses around the perimeter. The sheet glass is not limited to this shape. For example, two main surfaces of the sheet glass may not be parallel to each other, and a part or the whole of one or both of two main surfaces of the sheet glass may be curved. More specifically, the sheet glass may be flat sheet glass with no warpage or may be curved sheet glass with a curved surface.

### <Method for Producing Chemically Strengthened Glass>

As far as the above-described chemically strengthened glass of the present invention is produced, the method for producing the chemically strengthened glass is not particularly limited. The chemically strengthened glass of the present invention is produced by performing chemical strengthening treatment on glass for chemical strengthening.

For example, there may be mentioned an embodiment of the method (hereinafter also referred to as “first method”) for producing the chemically strengthened glass of the present invention, including: performing, on glass for chemical strengthening, first chemical strengthening treatment with a first molten salt containing 90 mass % or more of a Na salt and 2 mass % or more of a Li salt to the total mass of the first molten salt, and after the first chemical strengthening treatment, performing, on the glass for chemical strengthening, second chemical strengthening treatment with a second molten salt containing 90 mass % or more of a K salt to the total mass of the second molten salt.

Hereinafter, the first method for producing the chemically strengthened glass of the present invention will be described.

### [First Chemical Strengthening Treatment]

In the first method for producing the glass for chemical strengthening is subjected to the first chemical strengthening treatment with the first molten salt containing 90 mass % or more of a Na salt and 2 mass % or more of a Li salt to the total mass of the first molten salt.

The first chemical strengthening treatment is performed by bringing the glass for chemical strengthening into contact with the first molten salt. For example, the first chemical strengthening treatment can be performed by immersing the glass for chemical strengthening into the first molten salt.

Here, the glass for chemical strengthening is as described above in the section on the composition of the chemically strengthened glass of the present invention.

Preferable embodiments of the glass for chemical strengthening are the same as those described above.

It is particularly preferable to implement the first method for producing the chemically strengthened glass in the case where the glass for chemically strengthening has the base glass composition of the first embodiment.

More specifically, the glass for chemically strengthening preferably has a composition at a sheet thickness center position thereof including, in mole percentage on the oxide basis,
60 to 72% of SiO₂,
10 to 20% of Al₂O₃,
3 to 12% of Li₂O,
0.5 to 6% of Na₂O, and
1 to 3% of K₂O.

In the first molten salt, the content of the Na salt to the total mass of the first molten salt is 90 mass % or more, preferably 93 mass % or more, more preferably 95 mass % or more, still more preferably 96 mass % or more. In the first molten salt, the content of the Na salt to the total mass of the first molten salt is preferably 98 mass % or less and may be 97 mass % or less, or 96 mass % or less.

Examples of the Na salt in the first molten salt include sodium nitrate, sodium sulfate, sodium carbonate, sodium chloride and the like. Preferred is sodium nitrate.

In the first molten salt, the content of the Li salt to the total mass of the first molten salt is 2 mass % or more and may be 3 mass % or more, or 4 mass % or more. In the first molten salt, the content of the Li salt to the total mass of the first molten salt is preferably 10 mass % or less, more preferably 7 mass % or less, still more preferably 5 mass % or less.

Examples of the Li salt in the first molten salt include lithium nitrate, lithium sulfate, lithium carbonate and lithium chloride. Preferred is lithium nitrate.

The ratio of the content of the Li salt in the first molten salt to the content of Li₂O in the composition of the glass for chemical strengthening is, in molar ratio, preferably 0.1 or higher, more preferably 0.2 or higher, and may be 0.3 or higher. The above ratio is preferably 1.0 or lower, more preferably 0.8 or lower, still more preferably 0.6 or lower, particularly preferably 0.5 or lower.

The first molten salt may contain a component other than the Na salt and the Li salt. Examples of the component other than the Na salt and the Li salt include a K salt, a Rb (rubidium) salt, a Cs (cesium) salt and a Ag (silver) salt.

The first molten salt may preferably contain no component other than the Na salt and the Li salt. In other words, the first molten salt may preferably consist of the Na salt and the Li salt.

The treatment time of the first chemical strengthening treatment is preferably 30 minutes or more, more preferably 60 minutes or more, still more preferably 120 minutes or more, particularly preferably 150 minutes or more. The treatment time of the first chemical strengthening treatment is usually 720 minutes or less, preferably 360 minutes or less, more preferably 180 minutes or less.

The treatment temperature of the first chemical strengthening treatment is preferably 350° C. or higher, more preferably 380° C. or higher, still more preferably 400° C. or higher. The treatment temperature of the first chemical strengthening treatment is preferably 470° C. or lower, more preferably 440° C. or lower, still more preferably 420° C. or lower.

It is preferable that the treatment time and temperature of the first chemical strengthening treatment are in the respective preferable ranges described above.

The first chemical strengthening treatment enables ion exchange up to a deep layer portion of the glass while decreasing the amount of ion exchange, whereby the chemically strengthened glass of the present invention can be easily obtained.

### [Second Chemical Strengthening Treatment]

In the first method for producing the chemically strengthened glass of the present invention, the glass for chemical strengthening subjected to the first chemical strengthening treatment is further subjected to the second chemical strengthening treatment with the second molten salt containing 90 mass % or more of a K salt to the total mass of the second molten salt.

The second chemical strengthening treatment is performed by bringing the glass for chemical strengthening after the first chemical strengthening treatment into contact with the second molten glass. For example, the second chemical strengthening treatment is performed by immersing the glass for chemical strengthening after the first chemical strengthening treatment into the second molten glass.

The content of the K salt in the second molten salt to the total mass of the second molten salt is 90 mass % or more, preferably 93 mass % or more, more preferably 94 mass % or more, still more preferably 95 mass % or more, and may be 98 mass % or more, or 99 mass % or more. The content of the K salt in the second molten salt to the total mass of the second molten salt may be 100 mass %. In other words, the second molten salt may consist only of the K salt.

Examples of the K salt in the second molten salt include potassium nitrate, potassium sulfate, potassium carbonate and potassium chloride. Preferred is potassium nitride.

The second molten salt may contain a component other than the K salt. Examples of the component other than the K salt include a Li salt, a Na salt, a Rb salt, a Cs salt and a Ag salt.

The second molten salt may preferably contain no component other the K salt as mentioned above.

The treatment time of the second chemical strengthening treatment is preferably 20 minutes or more, more preferably 30 minutes or more, still more preferably 60 minutes or more, particularly preferably 90 minutes or more. The treatment time of the second chemical strengthening treatment is usually 360 minutes or less, preferably 180 minutes or less, more preferably 120 minutes or less.

The treatment temperature of the second chemical strengthening treatment is preferably 330° C. or higher, more preferably 360° C. or higher, still more preferably 380° C. or higher. The treatment temperature of the second chemical strengthening treatment is preferably 460° C. or lower, more preferably 430° C. or lower, still more preferably 410° C. or lower.

It is preferable that the treatment time and temperature of the second chemical strengthening treatment are in the respective preferable ranges described above.

Further, it is also preferable that the treatment time of the first chemical strengthening treatment is 150 minutes or more and the treatment time of the second chemical strengthening treatment is 90 minutes or more.

The chemically strengthened glass of the present invention can be produced by a method other than the above method.

Hereinafter, other embodiments of the method for producing the chemically strengthened glass of the present invention will be described.

Another embodiment of the method (hereinafter also referred to as “second method”) for producing the chemically strengthened glass of the present invention will be now described below.

The second method for producing the chemically strengthened glass of the present invention includes: performing, on glass for chemical strengthening, third chemical strengthening treatment with a third molten salt containing 50 mass % or more of a Na salt, 30 mass % or more of a K salt and 1 mass % or more of a Li salt to the total mass of the third molten salt; and after the third chemical strengthening treatment, performing, on the glass for chemical strengthening, fourth chemical strengthening treatment with a fourth molten salt containing 90 mass % or more of a K salt and 2 mass % or more of a Li salt to the total mass of the fourth molten salt.

### [Third Chemical Strengthening Treatment]

In the second method for producing the chemically strengthened glass of the present invention, the glass for chemical strengthening is subjected to the third chemical strengthening treatment with the third molten salt containing 50 mass % or more of a Na salt, 30 mass % or more of a K salt and 1 mass % or more of a Li salt to the total mass of the third molten salt.

The third chemical strengthening treatment is performed by bringing the glass for chemical strengthening into contact with the third molten salt. For example, the third chemical strengthening treatment can be performed by immersing the glass for chemical strengthening into the third molten salt.

Here, the glass for chemical strengthening is as described above in the section on the composition of the chemically strengthened glass of the present invention. Preferable embodiments of the glass for chemical strengthening are the same as those described above.

It is particularly preferable to implement the second method for producing the chemically strengthened glass of the present invention in the case where the glass for chemically strengthening has the base glass composition of the second embodiment with a P₂O₅ content of 1.0% or more.

The content of the Na salt in the third molten salt to the total mass of the third molten salt is 50 mass % or more, preferably 53 mass % or more, more preferably 55 mass % or more, still more preferably 58 mass % or more. The content of the Na salt in the third molten salt to the total mass of the third molten salt is 69 mass % or less, preferably 65 mass % or less, more preferably 62 mass % or less.

Examples of the Na salt in the third molten salt are the same as those of the Na salt in the first molten salt, and the same is preferred for the Na salt.

The content of the K salt in the third molten salt to the total mass of the third molten salt is 30 mass % or more, preferably 32 mass % or more, more preferably 35 mass % or more, still more preferably 37 mass % or more. The content of the K salt in the third molten salt to the total mass of the third molten salt is 49 mass % or less, preferably 45 mass % or less, more preferably 42 mass % or less, still more preferably 40 mass % or less.

Examples of the K salt in the third molten salt are the same as those of the K salt in the first molten salt, and the same is preferred for the K salt.

The content of the Li salt in the third molten salt to the total mass of the third molten salt is 1 mass % or more, preferably 2 mass % or more, and may be 3 mass % or more. The content of the Li salt in the third molten salt to the total mass of the third molten salt is 20 mass % or less, preferably 10 mass % or less, more preferably 5 mass % or less.

Examples of the Li salt in the third molten salt are the same as those of the Li salt in the first molten salt, and the same is preferred for the Li salt.

Further, the ratio of the content of the Li salt in the third molten salt to the content of Li₂O in the composition of the glass for chemical strengthening is, in molar ratio, preferably 0.05 or higher, more preferably 0.07 or higher, still more preferably 0.1 or higher. The above ratio is preferably 0.6 or lower, more preferably 0.5 or lower, still more preferably 0.35 or lower, particularly preferably 0.2 or lower.

The third molten salt may contain a component other than the Na salt, the K salt and the Li salt. Examples of the component other than the Na salt, the K salt and the Li salt include a Rb salt, a Cs salt and a Ag salt.

The third molten salt may preferably contain no component other than the Na salt, the K salt and the Li salt. In other words, the third molten salt may preferably consist of the Na salt, the K salt and the Li salt.

The treatment time of the third chemical strengthening treatment is preferably 60 minutes or more, 120 minutes or more, still more preferably 180 minutes or more. The treatment time of the third chemical strengthening treatment is usually 1440 minutes or less, preferably 720 minutes or less, more preferably 360 minutes or less.

The treatment temperature of the third chemical strengthening treatment is preferably 350° C. or higher, more preferably 380° C. or higher, still more preferably 400° C. or higher. The treatment temperature of the third chemical strengthening treatment is preferably 470° C. or lower, more preferably 440° C. or lower, still more preferably 420° C. or lower.

It is also preferable that the treatment time and temperature of the third chemical strengthening treatment are in the respective preferable ranges described above.

The third chemical strengthening treatment enables ion exchange up to a deep layer portion of the glass while decreasing the amount of ion exchange, whereby the chemically strengthened glass of the present invention can be easily obtained.

### [Fourth Chemical Strengthening Treatment]

In the second method for producing the chemically strengthened glass of the present invention, the glass for chemical strengthening subjected to the third chemical strengthening treatment is further subjected to the fourth chemical strengthening treatment with the fourth molten salt containing 90 mass % or more of a K salt and 2 mass % or more of a Li salt to the total mass of the fourth molten salt.

The fourth chemical strengthening treatment is performed by bringing the glass for chemical strengthening after the third chemical strengthening treatment into contact with the fourth molten glass. For example, the fourth chemical strengthening treatment is performed by immersing the glass for chemical strengthening after the third chemical strengthening treatment into the fourth molten glass.

The content of the K salt in the fourth molten salt to the total mass of the fourth molten salt is 90 mass % or more, preferably 91 mass % or more, more preferably 92 mass % or more, still more preferably 94 mass % or more. The content of the K salt in the fourth molten salt to the total mass of the fourth molten salt is 98 mass % or less, preferably 97 mass % or less, more preferably 96 mass % or less.

Examples of the K salt in the fourth molten salt are the same as those of the K salt in the second molten salt, and the same is preferred for the K salt.

The content of the Li salt in the fourth molten salt to the total mass of the fourth molten salt is 2 mass % or more, preferably 3 mass % or more, more preferably 4 mass % or more. The content of the Li salt in the fourth molten salt to the total mass of the fourth molten salt is 10 mass % or less, preferably 8 mass % or less, more preferably 7 mass % or less.

Examples of the Li salt in the fourth molten salt are the same as those of the Li salt in the first molten salt, and the same is preferred for the Li salt.

The fourth molten salt may contain a component other than the K salt and the Li salt. Examples of the component other than the K salt and the Li salt include a Na salt, a Rb salt, a Cs salt and a Ag salt.

The fourth molten salt may preferably contain no component other than the K salt and the Li salt.

The treatment time of the fourth chemical strengthening treatment is preferably 5 minutes or more, more preferably 10 minutes or more, still more preferably 20 minutes or more. The treatment time of the fourth chemical strengthening treatment is usually 360 minutes or less, preferably 180 minutes or less, more preferably 120 minutes or less, still more preferably 90 minutes or less.

The treatment temperature of the fourth chemical strengthening treatment is preferably 350° C. or higher, more preferably 380° C. or higher, still more preferably 400° C. or higher. The treatment temperature of the fourth chemical strengthening treatment is preferably 480° C. or lower, more preferably 450° C. or lower, still more preferably 430° C. or lower.

It is also preferable that the treatment time and temperature of the fourth chemical strengthening treatment are in the respective preferable ranges described above.

Still another embodiment of the method (hereinafter referred to as “third method”) for producing the chemically strengthened glass of the present invention includes: performing, on glass for chemical strengthening, fifth chemical strengthening treatment with a fifth molten salt containing 20 mass % or more of a Na salt and 60 mass % or more of a K salt to the total mass of the fifth molten salt.

### [Fifth Chemical Strengthening Treatment]

In the third method for producing the chemically strengthened glass of the present invention, the glass for chemical strengthening is subjected to the fifth chemical strengthening treatment with the fifth molten salt containing 60 mass % or more of a K salt and 20 mass % or more of a Na salt to the total mass of the fifth molten salt.

The fifth chemical strengthening treatment is performed by bringing the glass for chemical strengthening into contact with the fifth molten salt. For example, the fifth chemical strengthening treatment can be performed by immersing the glass for chemical strengthening into the fifth molten salt.

Here, the glass for chemical strengthening is as described above in the section on the composition of chemically strengthened glass of the present invention. Preferable embodiments of the glass for chemical strengthening are the same as those described above.

In particular, it is preferable to implement the third method for producing the chemically strengthened glass of the present invention in the case where the glass for chemically strengthening has the base glass composition of the second embodiment with a P₂O₅ content of 0.5% or more. In the case where the glass for chemical strengthening has the base glass composition of the second embodiment with a P₂O₅ content of 0.5% or more and less than 1.0%, it is more preferable to implement the third method for producing the chemically strengthened glass of the present invention.

The content of the K salt in the firth molten salt to the total mass of the fifth molten salt is 60 mass % or less, preferably 63 mass % or more, more preferably 65 mass % or more, still more preferably 67 mass % or more. The content of the K salt in the fifth molten salt to the total mass of the fifth molten salt is preferably 80 mass % or less, more preferably 77 mass % or less, still more preferably 75 mass % or less, yet more preferably 72 mass % or less.

Examples of the K salt in the fifth molten salt are the same as those of the K salt in the second molten salt, and the same is preferred for the K salt.

The content of the Na salt in the fifth molten salt to the total mass of the fifth molten salt is 20 mass % or more, preferably 22 mass % or more, more preferably 25 mass % or more, still more preferably 27 mass % or more. The content of the Na salt in the fifth molten salt to the total mass of the fifth molten salt is preferably 40 mass % or less, more preferably 37 mass % or less, still more preferably 35 mass % or less.

Examples of the Na salt in the fifth molten salt are the same as those of the Na salt in the first molten salt, and the same is preferred for the Na salt.

The fifth molten salt may contain a component other than the K salt and the Na salt. Examples of the component other than the K salt and the Na salt include a Li salt, a Rb salt, a Cs salt and a Ag salt.

The fifth molten salt may preferably contain no component other than the K salt and the Na salt. In other words, the fifth molten salt may preferably consist of the K salt and the Na salt.

The treatment time of the fifth chemical strengthening treatment is preferably 60 minutes or more, more preferably 120 minutes or more, still more preferably 180 minutes or more, and may be 360 minutes or more, or 720 minutes or more. The treatment time of the fifth chemical strengthening treatment is usually 1440 minutes or less, and may be 720 minutes or less, or 360 minutes or less.

The treatment temperature of the fifth chemical strengthening treatment is preferably 390° C. or higher, more preferably 420° C. or higher, still more preferably 440° C. or higher. The treatment temperature of the fifth chemical strengthening treatment is preferably 510° C. or lower, more preferably 480° C. or lower, still more preferably 460° C. or lower.

It is also preferable that the treatment time and temperature of the fifth chemical strengthening treatment are in the respective preferable ranges described above.

The fifth chemical strengthening treatment causes ion exchange of K while causing ion exchange of Na, whereby the chemically strengthened glass of the present invention can be easily obtained.

### <Uses>

The chemically strengthened glass of the present invention is useful, for example, as cover glasses.

The cover glasses are suitably applicable for the purposes of surface protection of displays, solar cell modules, and the like.

The chemically strengthened crystallized glass of the present invention is particularly useful as cover glasses for mobile devices such as mobile phones, smartphones, personal digital assistants (PDA), tablet terminals and the like. The chemically strengthened crystallized glass of the present invention is also useful for applications not intended for mobile uses, as typified by: cover glasses for display devices of televisions (TVs), personal computers (PCs), in-vehicle display systems, touch panels and the like; cover glasses on surfaces of solar cell modules; walls of elevators; walls (full-screen displays) of houses and buildings; architectural materials such as window glass; table tops; and interior parts of automobiles, aircrafts and the like. The chemically strengthened glass of the present invention is further useful as cover glasses for the above articles. Furthermore, the chemically strengthened glass of the present invention can be applied to casings with curved shapes and other applications by bending or bend-forming.

### EXAMPLES

Now, the present invention will be described in further detail with reference to Examples.

The materials, amounts used, proportions, treatment operations, treatment procedures etc. shown in the following Examples can be modified as appropriate without departing from the gist of the present invention. It should thus be understood that the scope of the present invention is by no means restricted to the following Examples.

In the following, Ex. 1 to 3, 5 and 7 to 9 correspond to Examples of the present invention; Ex. 4 and 6 correspond to Comparative Examples; and Ex. 10 and 11 correspond to Reference Examples.

### <Production of Chemically Strengthened Glass>

Glass materials A to C were each prepared by melting glass raw materials in a platinum crucible to have a glass composition in mole percentage on the oxide basis as shown in FIG. 1.

More specifically, oxides, hydroxides, carbonates and nitrates used as the glass raw materials were selected from commonly used glass raw materials as appropriate and weighed and mixed in amounts corresponding to 1000 g of glass.

The resulting raw material mixture was put in a platinum crucible, melted in a resistance-heating electric furnace at 1500 to 1700° C. for about 3 hours and subjected to degassing and homogenization to obtain a molten glass. The obtained molten glass was formed into glass blocks by pouring and holding the molten glass in a mold at a temperature higher by 50° C. than the glass transition temperature for 1 hour and cooling the molded glass to room temperature at a rate of 0.5° C./min. The glass block was processed into sheet glass by cutting and grinding. Both surfaces of the sheet glass were subjected to mirror finishing, and finally obtained was the sheet glass (glass for chemical strengthening) with a length of 120 mm, a width of 60 mm and a thickness of 0.5 mm or with a length of 120 mm, a width of 60 mm and a thickness of 0.6 mm.

On the other hand, the glass block were cut into sample pieces for measurements of fracture toughness value K_{IC} and Young's modulus by the above-described methods.

Here, the glass material B was, after processed into sheet glass, heat-treated by heating to and holding at 550° C. for 2 hours and heating to and holding at 720° C. for 2 hours.

The glass material C was, after processed into sheet glass, heat-treated by heating to and holding at 540° C. for 4 hours, heating to and holding at 600° C. for 4 hours and heating to and holding at 650° C. for 4 hours.

As for the glass materials B and C, the sample pieces for measurements of fracture toughness value K_{IC} and Young's modulus were obtained by performing the same heat treatment as above on the glass blocks.

TABLE 1

| | Glass | Composition | Composition | Composition |
|---|---|---|---|---|
| | material | A | B | C |
| Composition | SiO₂ | 66.2 | 61.0 | 68.6 |
| [mol %] | Al₂O₃ | 11.2 | 5.0 | 4.4 |
| | Li₂O | 10.4 | 21.0 | 21.3 |
| | Na₂O | 5.6 | 2.0 | 1.5 |
| | K₂O | 1.5 | 0.0 | 0.0 |
| | MgO | 3.1 | 5.0 | 0.0 |
| | CaO | 0.2 | 0.0 | 0.0 |
| | ZrO₂ | 1.3 | 3.0 | 1.7 |
| | SnO₂ | 0.0 | 0.0 | 0.10 |
| | P₂O₅ | 0.0 | 2.0 | 0.8 |
| | B₂O₃ | 0.0 | 0.0 | 1.6 |
| | Y₂O₃ | 0.5 | 1.0 | 0.0 |
| | SUM | 100.0 | 100.0 | 100.0 |

| | | | |
|---|---|---|---|
| R = Li₂O + Na₂O + K₂ | 17.5 | 23.0 | 22.8 |
| a = Li₂O/R | 0.594 | 0.913 | 0.934 |
| b = Na₂O/R | 0.320 | 0.087 | 0.066 |
| c = K₂O/R | 0.086 | 0.000 | 0.000 |
| Q = Al₂O₃/R | 0.640 | 0.217 | 0.193 |
| S = a × b × c | 0.0163 | 0.0000 | 0.0000 |
| K_{1c} [MPa · m^{1/2}] | 0.8 | 0.9 | 1.20 |
| Young's modulus [GPa] | 86.0 | 95.0 | 105.00 |

The above-obtained glasses for chemical strengthening (glass materials A to C) were chemically strengthened under the conditions shown in Table 2, thereby obtaining chemically strengthened glasses of Ex. 1 to 9.

In each of Ex. 10 and 11, the above-obtained glasses for chemical strengthening (glass materials A and B) were used as they were without chemical strengthening treatment.

### <Measurement of Stress Profile>

A stress profile of the chemically strengthened glass was measured by the method described above.

### <Measurement of Young's Modulus>

Using the sample piece cut out in the process of obtaining the glass material, the Young's modulus of the glass for chemical strengthening was measured by the ultrasonic pulse method according to JIS R1602. Here, the Young's modulus of the glass for chemical strengthening corresponds to the Young's modulus of the chemically strengthened glass at the sheet thickness center position.

Further, the Young's modulus of the chemically strengthened glass at the in-plane center position was measured by the same method as above and found to be the same as that measured using the sample piece. Thus, a description of the Young's modulus of the chemically strengthened glass at the in-plane center position will be omitted from the table below.

### <Measurement of Fracture Toughness Value>

Using the sample piece cut out in the process of obtaining the glass material, the fracture toughness value K_{IC} of the glass for chemical strengthening was measured by the above-described DCDC method.

### <Measurement of Transmittance>

The transmittance of the chemically strengthened glass was measured by the method described above.

The transmittance of the chemically strengthened glass of Ex. 5 was 91%, and the transmittance of the chemically strengthened glass of Ex. 7 was 92%.

### [Drop Strength Test]

The drop strength of the glass of each Ex. was measured by the following procedure.

A rectangular parallelepiped structural member of aluminum alloy having a width of 70 mm, a length of 130 mm, a thickness of 2 mm and a mass of 120 g was provided simulating a mobile device such as a smartphone.

The glass of each Ex. was attached to the widest surface of the structural member via a 0.5-mm adhesive tape.

Subsequently, the thus-obtained glass-attached structural member was dropped onto an abrasive material-side surface of #80 sandpaper where the abrasive material was silicon carbide, with the glass-attached side of the structural member facing the sandpaper. After the glass was dropped onto the sandpaper, the occurrence of breakage in the glass was checked. The above drop strength test was conducted by changing the height of drop of the glass-attached structural member. The height of drop at which breakage of the glass first occurred was recorded as an index of the drop strength. The height of drop at which breakage of the glass first occurred in the drop strength test using the #80 sandpaper is hereinafter also referred to as “#80SP breakage height”.

Furthermore, a drop strength test was further conducted in the same manner as above except that #180 sandpaper was used in place of the #80 sandpaper, and the height of drop at which breakage of the glass first occurred was recorded as an index of the drop strength.

The height of drop at which breakage of the glass first occurred in the drop strength test using the #180 sandpaper is hereinafter also referred to as “#180SP breakage height”.

### <Results>

The chemical strengthening treatment conditions and measurement and evaluation results of the chemically strengthened glass of each Ex. are shown in Table 2.

The respective parameters shown in the columns under the heading “Stress profile” in Table 2 are values measured by the methods described above.

In the column of “CT”, the absolute value of the stress value CT at the sheet thickness center position is shown.

In the column of “Slope (DOC to 120 μm)”, shown is the slope calculated from the compressive stress value at the depth of compressive stress layer DOC and the compressive stress value at the sheet thickness center position by the above-described method.

In the column of “Slope (@DOC)”, the absolute value of the first derivative value at the depth of compressive stress layer DOC, as determined by the method described above, is shown.

In the column of “Slope (@120 μm)”, the absolute value of the first derivative value at the depth of 120 μm from the glass surface, as determined by the method described above, is shown. In each of the stress profiles, the absolute value of the first derivative value was the greatest at the depth of 120 μm in the range from the depth of 120 μm from the glass surface to the sheet thickness center position.

The formulas (1) and (2) are as described above. In the case where the relationships of the formulas (1) and (2) are satisfied, the values shown in the corresponding columns of Table 2 are greater than or equal to 0.

TABLE 2

| | | | Ex. 1 | Ex. 2 | Ex. 3 | Ex. 4 | Ex. 5 | Ex. 6 |
|---|---|---|---|---|---|---|---|---|
| Glass for | Glass material | | Comp. A | Comp. A | Comp. A | Comp. A | Comp. B | Comp. B |
| chemical | Sheet thickness [mm] | | 0.5 | 0.5 | 0.5 | 0.5 | 0.6 | 0.6 |
| strengthening | K_{1c} [MPa · m^{1/2}] | | 0.8 | 0.8 | 0.8 | 0.8 | 0.88 | 0.88 |
| Chemical | Composition | LiNO₃ [mass %] | 4 | 3 | 2 | — | 2 | — |
| strengthening | of molten salt | NaNO₃ [mass %] | 96 | 97 | 98 | 100 | 38 | 100 |
| treatment 1 | | KNO₃ [mass %] | — | — | — | — | 60 | — |
| | Temperature [° C.] | | 410 | 410 | 410 | 410 | 410 | 390 |
| | Time [min] | | 150 | 150 | 150 | 150 | 330 | 420 |
| Chemical | Composition | LiNO₃ [mass %] | — | — | — | — | 5 | — |
| strengthening | of molten salt | NaNO₃ [mass %] | — | — | — | — | — | — |
| treatment 2 | | KNO₃ [mass %] | 100 | 100 | 100 | 100 | 95 | — |

| | | | | | | | |
|---|---|---|---|---|---|---|---|
| | Temperature [° C.] | 390 | 390 | 390 | 390 | 410 | — |
| | Time [min] | 90 | 90 | 90 | 90 | 30 | — |
| Stress | CT [MPa] | 77 | 84 | 90 | 105 | 71 | 151 |
| profile | CS₁₂₀ [MPa] | −21 | −23 | −25 | −32 | 15 | −51 |
| | CS₅₀ [MPa] | 63 | 71 | 74 | 96 | 143 | 247 |
| | DOC [μm] | 101 | 101 | 100 | 100 | 129 | 103 |
| | Slope (DOC to 120 μm) | −0.76 | −0.84 | −0.90 | −1.06 | −0.55 | −1.47 |
| | Slope (@DOC) | −1.14 | −1.26 | −1.37 | −1.70 | −1.54 | −3.55 |
| | Slope (@120 μm) | −0.98 | −1.07 | −1.16 | −1.40 | −1.75 | −2.68 |
| | First derivative ratio | 1.16 | 1.18 | 1.18 | 1.21 | 0.88 | 1.33 |
| | Right side of formula (1) − Left side of formula (1) | 13 | 6 | 0 | −15 | 2 | −78 |
| | Right side of formula (2) − Left side of formula (2) | 8 | 6 | 4 | −3 | 25 | −41 |
| Evaluations | #80SP Breakage height [cm] | 41 | 40 | 40 | 37 | 61 | 36 |
| | #180SP Breakage height [cm] | 71 | 74 | 75 | 83 | 106 | 145 |

| | | Ex. 7 | Ex. 8 | Ex. 9 | Ex. 10 | Ex. 11 |
|---|---|---|---|---|---|---|
| Glass for | Glass material | Comp. C | Comp. C | Comp. C | Comp. A | Comp. B |
| chemical | Sheet thickness [mm] | 0.6 | 0.6 | 0.6 | 0.5 | 0.5 |
| strengthening | K_{1c} [MPa · m^{1/2}] | 1.2 | 1.2 | 1.2 | 0.8 | 0.8 |

| | | | | | | | |
|---|---|---|---|---|---|---|---|
| Chemical | Composition | LiNO₃ [mass %] | — | — | — | — | — |
| strengthening | of molten salt | NaNO₃ [mass %] | 30 | 30 | 30 | — | — |
| treatment 1 | | KNO₃ [mass %] | 70 | 70 | 70 | — | — |

| | | | | | |
|---|---|---|---|---|---|
| Temperature [° C.] | 450 | 450 | 450 | — | — |
| Time [min] | 180 | 420 | 900 | — | — |

| | | | | | | | |
|---|---|---|---|---|---|---|---|
| Chemical | Composition | LiNO₃ [mass %] | — | — | — | — | — |
| strengthening | of molten salt | NaNO₃ [mass %] | — | — | — | — | — |
| treatment 2 | | KNO₃ [mass %] | — | — | — | — | — |

| | | | | | | |
|---|---|---|---|---|---|---|
| | Temperature [° C.] | — | — | — | — | — |
| | Time [min] | — | — | — | — | — |
| Stress profile | CT [MPa] | 48 | 54 | 56 | 0 | 0 |
| | CS₁₂₀ [MPa] | −10 | −8 | −4 | 0 | 0 |
| | CS₅₀ [MPa] | 45 | 54 | 51 | 0 | 0 |
| | DOC [μm] | 105 | 110 | 114 | 0 | 0 |
| | Slope (DOC to 120 μm) | −0.46 | −0.49 | −0.49 | 0.00 | 0.00 |
| | Slope (@DOC) | −0.67 | −0.67 | −0.70 | 0.00 | 0.00 |
| | Slope (@120 μm) | −0.57 | −0.64 | −0.63 | 0.00 | 0.00 |
| | First derivative ratio | 1.19 | 1.05 | 1.12 | — | — |
| | Right side of formula (1) − Left side of formula (1) | 25 | 19 | 17 | 0 | 0 |
| | Right side of formula (2) − Left side of formula (2) | 0 | 2 | 6 | 29 | 29 |
| Evaluations | #80SP Breakage height [cm] | 75 | 76 | 77 | 49 | 55 |
| | #180SP Breakage height [cm] | 93 | 96 | 95 | 48 | 53 |

Comp.: Composition

As is seen from the results shown in Table 2, particularly from comparison of the results of Ex. 4, 6, 10 and 11 with the results of the other Ex., the chemically strengthened glass was excellent in drop strength (#80SP breakage height and #180SP breakage height) when the relationship of the formula (1) was satisfied by the stress CT at the sheet thickness center position and the relationship of the formula (2) was satisfied by the compressive stress C₁₂₀ at the depth of 120 μm from the glass surface.

As is seen from comparison of the results of Ex. 7 with the results of Ex. 8 and 9, the chemically strengthened glass was further excellent in drop strength (#80SP breakage height and #180SP breakage height) when the first derivative ratio was from 0.90 to 1.15.

The entire disclosure of Japanese Patent Application No. 2024-161606 filed on Sep. 19, 2024, including specification, claims, drawings and summary, is incorporated herein by reference in its entirety.

What is claimed is:

1. Chemically strengthened glass satisfying relationships of the following formulas (1) and (2):
$$\vert CT \vert \leq - 170 t + 175 \qquad ( 1 )$$
$$190 t - 124 \leq {CS}_{120} \qquad ( 2 )$$
where CT represents stress, in units of MPa, at a sheet thickness center position of the chemically strengthened glass; |CT| represents an absolute value of the stress CT; t represents a sheet thickness of the chemically strengthened glass in units of mm; and CS₁₂₀ represents compressive stress, in units of MPa, at a depth of 120 μm from a surface of the chemically strengthened glass.

2. The chemically strengthened glass according to claim 1, wherein a depth of compressive stress layer DOC of the chemically strengthened glass is greater than or equal to 0.20 times the sheet thickness of the chemically strengthened glass.

3. The chemically strengthened glass according to claim 2, wherein a stress profile of the chemically strengthened glass has a slope with an absolute value of 1.00 or less from the depth of compressive stress layer DOC to the sheet thickness center position.

4. The chemically strengthened glass according to claim 1, wherein the chemically strengthened glass satisfies a relationship of the following formula (3):
$$150 t - 50 \leq {CS}_{50} \qquad ( 3 )$$
where CS₅₀ represents compressive stress, in units of MPa, at a depth of 50 μm from the surface of the chemically strengthened glass; and t represents the sheet thickness of the chemically strengthened glass in units of mm.

5. The chemically strengthened glass according to claim 1, wherein the chemically strengthened glass has a Young's modulus of 80 GPa or higher at an in-plane center position thereof.

6. The chemically strengthened glass according to claim 1, wherein the chemically strengthened glass has a fracture toughness value K_{IC} of 0.80 MPa·m^{1/2} or higher at an in-plane center position thereof.

7. The chemically strengthened glass according to claim 1, wherein the chemically strengthened glass has a composition at the sheet thickness center position thereof comprising, in mole percentage on an oxide basis,
55 to 75% of SiO₂,
3 to 18% of Al₂O₃,
17 to 30% of Li₂O,
0 to 3% of Na₂O,
0 to 1% of K₂O,
0 to 10% of MgO,
0 to 10% of CaO,
0 to 5% of SrO,
0 to 5% of ZnO,
0 to 3% of TiO₂,
0 to 5% of ZrO₂,
0 to 1% of SnO₂,
0 to 3% of P₂O₅,
0 to 10% of B₂O₃, and
0 to 3% of Y₂O₃.

8. The chemically strengthened glass according to claim 1, wherein the chemically strengthened glass is in the form of crystallized glass and has a transmittance of 85% or higher.

9. The chemically strengthened glass according to claim 1, wherein the compressive stress CS₁₂₀ is 0 MPa or lower.

10. The chemically strengthened glass according to claim 1, wherein the sheet thickness is 0.6 mm or smaller.

11. The chemically strengthened glass according to claim 1, wherein a stress profile of the chemically strengthened glass, as measured in a depth direction by a scattered light photoelastic stress meter, has a first derivative value with an absolute value of 1.80 or less at any depth from the depth of 120 μm from the surface to the sheet thickness center position.

12. The chemically strengthened glass according to claim 2, wherein a stress profile of the chemically strengthened glass, as measured in a depth direction by a scattered light photoelastic stress meter, has a first derivative value with an absolute value of 1.80 or less at the depth of compressive stress layer DOC.

13. The chemically strengthened glass according to claim 2, wherein a stress profile of the chemically strengthened glass, as measured in a depth direction by a scattered light photoelastic stress meter device, has a first derivative value such that a value obtained by dividing an absolute value of the first derivative value at the depth of compressive stress layer DOC by an absolute value of the first derivative value at the depth of 120 μm from the surface is 1.20 or less.

14. A method for producing chemically strengthened glass as defined in claim 1, comprising:
performing, on glass for chemical strengthening, first chemical strengthening treatment with a first molten salt containing 90 mass % or more of a sodium salt and 2 mass % or more of a lithium salt to the total mass of the first molten salt; and
after the first chemical strengthening treatment, performing, on the glass for chemical strengthening, second chemical strengthening treatment with a second molten salt containing 90 mass % or more of a potassium salt to the total mass of the second molten salt,
the glass for chemical strengthening having a composition at a sheet thickness center position thereof comprising, in mole percentage on an oxide basis,
60 to 72% of SiO₂,
10 to 20% of Al₂O₃,
3 to 12% of Li₂O,
0.5 to 6% of Na₂O, and
1 to 3% of K₂O.

15. The method for producing chemically strengthened glass according to claim 14, wherein the ratio of the content of the lithium salt in the first molten salt to the content of Li₂O in the composition of the chemically strengthened glass is from 0.1 to 1.0 in terms of molar ratio.

16. The method for producing chemically strengthened glass according to claim 14, wherein a treatment time of the first chemical strengthening treatment is 150 minutes or more, and a treatment time of the second chemical strengthening treatment is 90 minutes or more.

17. A cover glass comprising the chemically strengthened glass as defined in any one of claim 1.

18. A solar cell module comprising the cover glass as defined in claim 17.
